(19) United States
(12) Patent Application Publication
(10) Pub. No.: US 2019/0179979 A1
(43) Pub. Date: Jun. 13, 2019

(54) Simulated Sensor Testing

(71) Applicant: Uber Technologies, Inc., San Francisco, CA (US)

(72) Inventor: Peter Melick, Pittsburgh, PA (US)

(21) Appl. No.: 15/893,729

(22) Filed: Feb. 12, 2018

Related U.S. Application Data
(60) Provisional application No. 62/598,125, filed on Dec. 13, 2017.

(51) Int. Cl. G06F 17/50; G01S 17/93; G01S 7/497; G01P 3/00; G01P 21/02; G01C 21/28; G01C 25/00; G05D 1/02

(52) U.S. Cl. CPC G06F 17/5009; G01S 17/936; G01S 7/497; G01P 3/00; G05D 1/0088; G01C 21/28; G01C 25/00; G05D 1/0221; G01P 21/02

(57) ABSTRACT

Systems, methods, tangible non-transitory computer-readable media, and devices for autonomous vehicle operation are provided. For example, a computing system can obtain a scene that includes simulated objects associated with simulated physical properties. The computing system can generate sensor data, which can include simulated sensor interactions for the scene. The simulated sensor interactions can include simulated sensors detecting the simulated objects. Further, the simulated sensors can include simulated sensor properties. The simulated sensor interactions that satisfy one or more perception criteria of an autonomous vehicle perception system can be determined, based at least in part on the sensor data. Furthermore, changes for the autonomous vehicle perception system can be generated, based at least in part on the simulated sensor interactions that satisfy the one or more perception criteria.

### RELATED APPLICATION

The present application is based on and claims benefit of U.S. Provisional Patent Application No. 62/598,125 having a filing date of Dec. 13, 2017, which is incorporated by reference herein.

### FIELD

The present disclosure relates generally to the testing and optimization of sensors for an autonomous vehicle.

### BACKGROUND

Vehicles, including autonomous vehicles, can receive data based on the state of the environment around the vehicle including the state of objects in the environment. This data can be used to safely guide the autonomous vehicle through the environment. Further, effective guidance of the autonomous vehicle through an environment can be influenced by the quality of outputs received from the autonomous vehicle systems that detect the environment. However, testing the autonomous vehicle systems used to detect the state of an environment can be time consuming, resource intensive, and require a great deal of manual interaction. Accordingly, there exists a demand for an improved way to address the challenge of testing and improving the performance of vehicle systems that are used to detect the state of the environment.

### SUMMARY

Aspects and advantages of embodiments of the present disclosure will be set forth in part in the following description, or may be learned from the description, or may be learned through practice of the embodiments.

An example aspect of the present disclosure is directed to a computer-implemented method of autonomous vehicle operation. The computer-implemented method of autonomous vehicle operation can include obtaining, by a computing system including one or more computing devices, a scene including one or more simulated objects associated with one or more simulated physical properties. The method can also include generating, by the computing system, sensor data including one or more simulated sensor interactions for the scene. The one or more simulated sensor interactions can include one or more simulated sensors detecting the one or more simulated objects. Further, the one or more simulated sensors can include one or more simulated sensor properties. The method can include determining, by the computing system and based in part on the sensor data, the one or more simulated sensor interactions that satisfy one or more perception criteria of an autonomous vehicle perception system. The method can also include generating, by the computing system, based in part on the one or more simulated sensor interactions that satisfy the one or more perception criteria, one or more changes for the autonomous vehicle perception system.

Another example aspect of the present disclosure is directed to one or more tangible, non-transitory computer-readable media storing computer-readable instructions that when executed by one or more processors cause the one or more processors to perform operations. The operations can include obtaining a scene including one or more simulated objects associated with one or more simulated physical properties. The operations can also include generating sensor data including one or more simulated sensor interactions for the scene. The one or more simulated sensor interactions can include one or more simulated sensors detecting the one or more simulated objects. Further, the one or more simulated sensors can include one or more simulated sensor properties. The operations can also include determining, based at least in part on the sensor data, the one or more simulated sensor interactions that satisfy one or more perception criteria of an autonomous vehicle perception system. Furthermore, the operations can include generating, based at least in part on the one or more simulated sensor interactions that satisfy the one or more perception criteria, one or more changes for the autonomous vehicle perception system.

Another example aspect of the present disclosure is directed to a computing system comprising one or more processors and one or more non-transitory computer-readable media storing instructions that when executed by the one or more processors cause the one or more processors to perform operations. The operations can include obtaining a scene including one or more simulated objects associated with one or more simulated physical properties. The operations can also include generating sensor data including one or more simulated sensor interactions for the scene. The one or more simulated sensor interactions can include one or more simulated sensors detecting the one or more simulated objects. Further, the one or more simulated sensors can include one or more simulated sensor properties. The operations can also include determining, based at least in part on the sensor data, the one or more simulated sensor interactions that satisfy one or more perception criteria of an autonomous vehicle perception system. Furthermore, the operations can include generating, based at least in part on the one or more simulated sensor interactions that satisfy the one or more perception criteria, one or more changes for the autonomous vehicle perception system.

Other example aspects of the present disclosure are directed to other systems, methods, vehicles, apparatuses, tangible non-transitory computer-readable media, and devices for autonomous vehicle operation including obtaining, receiving, generating, and/or processing one or more portions of a simulated environment that includes one or more simulated sensor interactions.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a diagram of an example system according to example embodiments of the present disclosure;

FIG. 2 depicts an example of a sensor testing and optimization system according to example embodiments of the present disclosure;

FIG. 3 depicts an example of a scene generated by computing system according to example embodiments of the present disclosure;

FIG. 4 depicts a flow diagram of an example method of sensor testing and optimization according to example embodiments of the present disclosure;

FIG. 5 depicts a flow diagram of an example method of sensor testing and optimization according to example embodiments of the present disclosure;

FIG. 6 depicts a flow diagram of an example method of sensor testing and optimization according to example embodiments of the present disclosure;

FIG. 7 depicts a flow diagram of an example method of sensor testing and optimization according to example embodiments of the present disclosure; and

FIG. 8 depicts a diagram of an example system according to example embodiments of the present disclosure.

### DETAILED DESCRIPTION

Example aspects of the present disclosure are directed at the optimization of sensor performance for an autonomous vehicle perception system based on the generation and analysis of one or more simulated sensor interactions resulting from one or more simulated sensors in a simulated environment (e.g., a scene) that includes one or more simulated objects. More particularly, aspects of the present disclosure include one or more computing systems (e.g., a sensor optimization system) that can obtain and/or generate a scene including simulated objects that are posed according to pose properties, generating simulated sensor interactions between simulated sensors and the scene, determining simulated sensor interactions that satisfy perception criteria associated with one or more performance characteristics of an autonomous vehicle perception system (e.g., criteria associated with improving the accuracy of the autonomous vehicle perception system), and generating changes in the autonomous vehicle perception system based on the simulated sensor interactions that satisfy the perception criteria (e.g., changing the location of sensors or the type of sensors on an autonomous vehicle in order to improve detection of objects by the sensors).

By way of example, the sensor optimization system can generate a scene comprising a simulated autonomous vehicle that includes a simulated light detection and ranging (LIDAR) sensor. The scene can specify that the simulated autonomous vehicle travels down a simulated street and uses the simulated LIDAR sensor to detect two simulated pedestrians. As the simulation runs, the sensor optimization system can, based on one or more simulated sensor properties (e.g., sensor range and/or spin rate) of the simulated LIDAR sensor, generate one or more simulated sensor interactions. The one or more simulated sensor interactions can include one or more simulated sensors detecting one or more simulated objects and can include one or more outputs that are generated based on the one or more pose properties and the one or more simulated sensor properties. For example, the one or more sensor interactions of one or more simulated LIDAR sensors can include detection of one or more simulated objects and generation of simulated LIDAR point cloud data. As such, the one or more simulated sensor interactions can be used as inputs to an autonomous vehicle perception system and thereby improve the performance of the autonomous vehicle perception system.

The sensor optimization system can use one or more rendering techniques to generate the one or more simulated sensor interactions. For example, the one or more rendering techniques can include ray tracing, ray casting, and/or rasterization. Based on the one or more simulated sensor interactions that are generated, the sensor optimization system can determine the one or more simulated sensor interactions that satisfy one or more perception criteria. For example, the sensor optimization system can determine which of the one or more simulated sensor interactions produce sensor data that results in high object recognition accuracy. Further, the simulated sensor interactions can be used to adjust the autonomous vehicle perception system based on the different simulated sensor properties (e.g., increasing or decreasing the spin rate for the LIDAR sensor).

The disclosed technology can include one or more systems including a sensor optimization system (e.g., a computing system including one or more computing devices with one or more processors and a memory) and/or an autonomous vehicle computing system. The autonomous vehicle computing system can include various sub-systems. For instance, the autonomous vehicle computing system can include an autonomous vehicle perception system that can receive sensor data based on sensor output from simulated sensors (e.g., sensor output generated by the sensor optimization system) and/or physical sensors (e.g., actual physical sensors including one or more LIDAR sensors, one or more radar devices, and/or one or more cameras).

The disclosed technology can, in some embodiments, be implemented in an offline testing scenario. The autonomous vehicle perception system can include, for example, a virtual perception system that is configured for testing in the offline testing scenario. The sensor optimization system can process, generate, and/or exchange (e.g., send and/or receive) signals or data, including signals or data exchanged with one or more computing systems including remote computing systems.

The sensor optimization system can obtain a scene including one or more simulated objects (e.g., obtain from a computing device or storage device associated with a dataset including data associated with one or more simulated objects). The scene can be based in part on one or more data structures in which one or more simulated objects (e.g., one or more data objects, each of which is associated with a set of properties) can be generated to determine one or more simulated sensor interactions between the one or more simulated sensors and the one or more simulated objects. The one or more simulated objects can be associated with one or more simulated physical properties associated with a location (e.g., a set of coordinates associated with the location of the one or more simulated objects within the scene), a velocity, spatial dimensions (e.g., a three-dimensional mesh of the one or more simulated objects), or a path (e.g., a set of locations that the one or more simulated objects will traverse and/or a corresponding set of times that the one or more simulated objects will be at the set of locations) of the one or more simulated objects.

The sensor optimization system can generate one or more simulated sensor interactions for the scene. The one or more simulated sensors can operate according to one or more simulated sensor properties. For example, the one or more simulated sensor interactions can be associated with detection capabilities of the one or more simulated sensors. The one or more simulated sensor properties of the one or more simulated sensors can include, for example, a spin rate (e.g., a rate at which a simulated LIDAR sensor spins), a point density (e.g., a density of a simulated LIDAR point cloud), a field of view, a height (e.g., a height of a simulated sensor positioned on a simulated autonomous vehicle object), a frequency (e.g., a frequency with which a sensor generates sensor output), an amplitude (e.g., the intensity of light from a simulated optical sensor), a focal length, a range, a sensitivity, a latency, a linearity, or a resolution.

In some embodiments, the one or more simulated sensor interactions can be based in part on one or more simulated sensors detecting the one or more simulated objects in the scene. The detection by the one or more simulated sensors can include detecting one or more three-dimensional positions associated with the spatial dimensions of the one or more simulated objects. For example, the one or more simulated physical properties associated with the spatial dimensions of the one or more simulated objects can be based on a three-dimensional mesh that is generated for each of the one or more simulated objects. The simulated sensor output (e.g., simulated sensor output from a simulated LIDAR device) can include sensor data from the one or more simulated sensors. By way of example, the sensor data can include one or more three-dimensional points (e.g., simulated LIDAR point cloud data) associated with the one or more three-dimensional positions of the one or more simulated objects.

The sensor optimization system can determine, based in part on the sensor data, the one or more simulated sensor interactions that satisfy one or more perception criteria associated with performance of a computing system (e.g., an autonomous vehicle perception system). The one or more perception criteria can be based in part on characteristics of the one or more simulated sensor interactions including, for example, one or more thresholds associated with the one or more simulated sensor properties (e.g., the range of the one or more simulated sensors), the accuracy of the one or more simulated sensors, and/or the sensitivity of the one or more simulated sensors.

The sensor optimization system can generate, based in part on the one or more simulated sensor interactions that satisfy the one or more perception criteria, data indicative of one or more changes in the autonomous vehicle perception system. For example, in an autonomous vehicle with two sensors, the one or more simulated sensor interactions can indicate that a first simulated sensor has superior range to a second simulated sensor in certain scenes (e.g., the first simulated sensor may have longer range in a scene that is very dark) and can generate one or more changes in the autonomous vehicle perception system (e.g., weighing the autonomous vehicle perception system to use more sensor data from the first sensor in dark conditions). Further, in some embodiments, the one or more changes to the autonomous vehicle perception system can be performed via the modification of data in the autonomous vehicle perception system that is associated with the operation of one or more sensors of an autonomous vehicle (e.g., modifying data structures that indicate a spin rate of one or more LIDAR sensors in the autonomous vehicle).

In some embodiments, the one or more simulated sensor interactions can include one or more obfuscating interactions that reduce the detection capabilities of the one or more simulated sensors. The one or more obfuscating interactions can simulate physical obfuscating interactions that can result from the interaction between the simulated sensors and the one or more simulated objects in the scene (e.g., other simulated sensors, simulated autonomous car, simulated traffic lights, and/or simulated glass windows). The one or more obfuscating interactions can include sensor cross-talk, sensor noise, sensor blooming, spinning sensor distortion, sensor lens distortion (e.g., barrel distortion or pincushion distortion in a simulated optical lens), sensor tangential distortion (e.g., an optical aberration caused by a non-parallel simulated lens and simulated sensor), sensor banding, or sensor color imbalance (e.g., a white balance that obscures image detail).

In some embodiments, the one or more simulated sensors can include a spinning sensor. The spinning sensor can include one or more simulated sensor properties that has detection capabilities of the one or more simulated sensors based at least in part on a simulated relative velocity distortion associated with a spin rate (e.g., the number of rotations per minute that the one or more simulated sensors make as the one or more sensors detect a simulated environment) of the spinning sensor. For example, the spinning sensor can include a simulated LIDAR device that spins to detect a radius around the sensor) and the velocity of the one or more objects relative to the spinning sensor.

The sensor optimization system can adjust the one or more simulated sensor properties of the one or more simulated sensors based at least in part on the one or more obfuscating interactions that reduce the detection capabilities of the one or more simulated sensors. For example, the sensor optimization system can adjust the one or more simulated sensor properties of the one or more simulated sensors that are changeable to counteract the effects of the one or more obfuscating interactions (e.g., changing the focal length of an optical sensor). Accordingly, based on the adjustment to the one or more simulated sensor properties of the one or more simulated sensors, one or more physical sensors upon which the one or more simulated sensor properties are based can be adjusted in a similar way.

The sensor optimization system can generate sensor data based at least in part on the one or more simulated sensors detecting the one or more simulated objects from a plurality of simulated sensor positions within the scene. Each of the plurality of simulated sensor positions can include an x-coordinate location, a y-coordinate location, and a z-coordinate location of the one or more simulated sensors with respect to a ground plane of the scene and/or an angle of the one or more simulated sensors with respect to the ground plane of the scene. In some embodiments, the one or more simulated sensor interactions can be based at least in part on the one or more simulated sensors detecting the one or more simulated objects from the plurality of simulated sensor positions within the scene.

The sensor optimization system can generate sensor data based at least in part on the one or more simulated sensors detecting the one or more simulated objects using a plurality of simulated sensor types. For example, the plurality of simulated sensor types can include different types of simulated sensors (e.g., simulated sonar sensors and/or simulated optical sensors including simulated LIDAR) that are associated with different types of sensor outputs. For each of the plurality of simulated sensor types, the one or more simulated sensor properties or values associated with the one or more simulated sensor properties can be different. In some embodiments, the one or more simulated sensor interactions can be based at least in part on the one or more simulated sensors detecting the one or more simulated objects using the plurality of simulated sensor types.

The sensor optimization system can generate sensor data based at least in part on the one or more simulated sensors detecting the one or more simulated objects using a plurality of activation sequences. The plurality of activation sequences can include an order and/or a timing of activating the one or more simulated sensors. As the one or more simulated sensors can affect the way in which other simulated sensors detect the simulated objects (e.g., crosstalk), the one or more simulated sensor interactions can change based on the order in which the sensors are activated, and/or the time interval between activating different sensors. In some embodiments, the one or more simulated sensor interactions can be based at least in part on the one or more simulated sensors detecting the one or more simulated objects in the plurality of activation sequences.

The sensor optimization system can generate sensor data based at least in part on the one or more simulated sensors detecting the one or more simulated objects based at least in part on a plurality of utilization levels associated with a number of the one or more simulated sensors that are activated at a time. For example, the one or more simulated sensor interactions can include one or more sensor interactions for various numbers of sensors (e.g., one sensor, three sensors, and/or five sensors). The different number of sensors in the one or more sensor interactions can generate different sensor outputs that can provide a different indication of the state of the scene (e.g., more sensors can result in different coverage of an area and can produce crosstalk or other interference). In some embodiments, the one or more simulated sensor interactions can be based at least in part on the one or more simulated sensors detecting the one or more simulated objects based in part on the plurality of utilization levels.

The sensor optimization system can generate sensor data based at least in part on the one or more simulated sensors detecting the one or more simulated objects using a plurality of sample rates associated with a frequency with which the one or more simulated sensors detect the one or more simulated objects. Each of the plurality of sample rates can be associated with a frequency (e.g., a spin rate of a LIDAR sensor and/or a number of frames per second captured by a camera) at which the one or more simulated sensors generate the simulated sensor output. In some embodiments, the one or more simulated sensor interactions can be based at least in part on the one or more simulated sensors detecting the one or more simulated objects using the plurality of sample rates.

In some embodiments, the one or more simulated sensor properties can be based at least in part on one or more sensor properties of one or more physical sensors. Further, the specifications and performance characteristics of one or more physical sensors can be determined based on one or more sensor interactions of the one or more physical sensors with one or more physical objects. For example, the range of a physical sensor can be determined by testing the physical sensor in a variety of different environmental conditions (e.g., at night, in the rain, or on a cloudy day) and the determined range of the physical sensor can be used as the basis for a simulated sensor. The one or more physical sensors upon which the one or more sensor properties can be based can include one or more light detection and ranging devices (LIDAR), one or more radar devices, one or more sonar devices, one or more cameras, and/or other types of sensors.

The sensor optimization system can receive physical sensor data based in part on one or more physical sensor interactions including one or more physical sensors detecting (e.g., generating sensor outputs from a physical sensor including LIDAR, a camera, and/or sonar device) one or more physical objects (e.g., people, vehicles, and/or buildings) and one or more physical pose properties of the one or more physical objects. The physical sensor data can be based on sensor outputs from physical sensors that detect one or more physical pose properties of the one or more physical objects. The one or more physical pose properties can be associated with one or more physical locations (e.g., a geographical location), one or more physical velocities, one or more physical spatial dimensions, one or more physical paths associated with the one or more physical objects, and/or other properties.

The sensor optimization system can pose the one or more simulated objects (e.g., the one or more simulated objects in the scene) based at least in part on the one or more physical pose properties of the one or more physical objects in the physical environment. In some embodiments, the scene can be based at least in part on the physical sensor data.

The sensor optimization system can determine one or more differences between the one or more simulated sensor interactions and the one or more physical sensor interactions. For example, the sensor optimization system can determine the one or more differences based on a comparison of one or more properties of the one or more simulated sensor interactions and the one or more physical sensor interactions including the range, point density (e.g., point cloud density of a LIDAR point cloud), and/or accuracy of the one or more simulated sensors and the one or more physical sensors.

The sensor optimization system can adjust the one or more simulated interactions based at least in part on the one or more differences between the one or more simulated sensor interactions and the one or more physical sensor interactions. For example, the one or more simulated sensor interactions can include sensor output that is based at least in part on one or more simulated sensor properties indicating that the range of a simulated sensor under a set of predetermined environmental conditions is fifty meters. The differences between the simulated sensor and a physical sensor upon which the simulated sensor is based can show that the physical sensor only has a range of thirty-five meters under the set of predetermined environmental conditions in a physical environment. As such, the one or more simulated interactions can be adjusted so that the range of the simulated sensor under simulated conditions is the same as the range of the physical sensor in similar physical conditions.

The sensor optimization system can associate the one or more simulated objects with one or more classified object labels. For example, a machine-learned model can be associated with the autonomous vehicle perception system and can generate classified object labels based on sensor data. The classified object labels associated with the one or more simulated objects can be generated in the same format as the classified object labels generated by the machine-learned model.

The sensor optimization system can send the sensor data, including sensor data associated with one or more classified objet labels, to a machine-learned model associated with the autonomous vehicle perception system. Accordingly, the sensor data associated with the one or more classified object labels can be used as input to train the machine-learned model associated with the autonomous vehicle perception system. For example, the machine-learned model associated with the autonomous vehicle perception system can use the sensor data as sensor input that is used to detect and/or identify the one or more simulated objects.

The sensor optimization system can compare the one or more classified object labels to one or more machine-learned model classified object labels generated by the machine-learned model from the sensor data. In some embodiments, satisfying the one or more perception criteria can be based at least in part on a magnitude of one or more differences between the one or more classified object labels and the one or more machine-learned model classified object labels. For example, a number of the one or more differences can be compared to a threshold number of differences and satisfying the one or more perception criteria can include the number of the one or more differences exceeding the threshold number of differences.

The systems, methods, devices, and tangible, non-transitory computer-readable media in the disclosed technology can provide a variety of technical effects and benefits to the overall operation of autonomous vehicles including improving the performance of autonomous vehicle perception systems. In particular, the disclosed technology leverages the advantages of a simulated testing environment (e.g., a scene generated by the sensor optimization system) that can simulate a greater number and variety of testing situations than would be practicable in a testing scenario involving the use of physical vehicles, physical sensors, and other physical objects (e.g., actual pedestrians) in a physical environment.

For example, the disclosed technology offers the benefits of greater safety by operating within the confines of a simulated testing environment that is generated by one or more computing systems. Since the objects within the simulated testing environment are simulated, any adverse outcomes or sub-optimal performance by the one or more simulated sensors do not have an adverse effect in the physical world.

The disclosed technology can perform a greater number and a greater variety of tests than could be performed in a non-simulated environment within the same period of time. For example, the sensor optimization system can include multiple computing devices that can be used to generate millions of scenes and determine millions of sensor interactions for the scenes in a time frame that would not be possible in a physical environment. Further, the disclosed technology can set up a scene (e.g., change the one or more simulated objects and the one or more properties of the one or more simulated objects) more quickly than is possible in a physical environment. Additionally, because the sensor optimization system generates the scenes, various scenes that correspond to extreme or unusual environmental conditions that do not occur often, or would be difficult to test in the real world, can be generated quickly.

The sensor optimization system can generate simulated sensors and simulated sensor interactions that are based on sensor outputs from physical sensors. The sensor optimization can then compare the simulated sensor interactions to physical sensor interactions from the physical sensors that are the basis for the simulated sensor interactions. Accordingly, an autonomous vehicle perception system that includes the physical sensors can be adjusted based on the differences between the simulated sensor interactions and the physical sensor interactions. The adjustment to the autonomous vehicle perception system can result in improved performance of the autonomous vehicle perception system (e.g., improved sensor range, less sensor noise, and lower computational resource utilization).

Furthermore, by simulating different degrees of degraded sensor calibration (e.g., imperfect or sub-optimal measurement of where one or more sensors are located and/or positioned), the disclosed technology can facilitate testing of the sensitivity of an autonomous vehicle's software using the degraded (e.g., miscalibrated) sensors. As such, the sensors in the autonomous vehicle can be better positioned (e.g., the positions and/or locations of sensors on an autonomous vehicle can be adjusted in order to improve sensor range and/or accuracy) based on the simulated sensor interactions.

Accordingly, the disclosed technology provides more effective sensor optimization by leveraging the benefits of a simulated testing environment. In this way, various systems including an autonomous vehicle perception system can benefit from the improved sensor performance that is the result of more effective sensor testing.

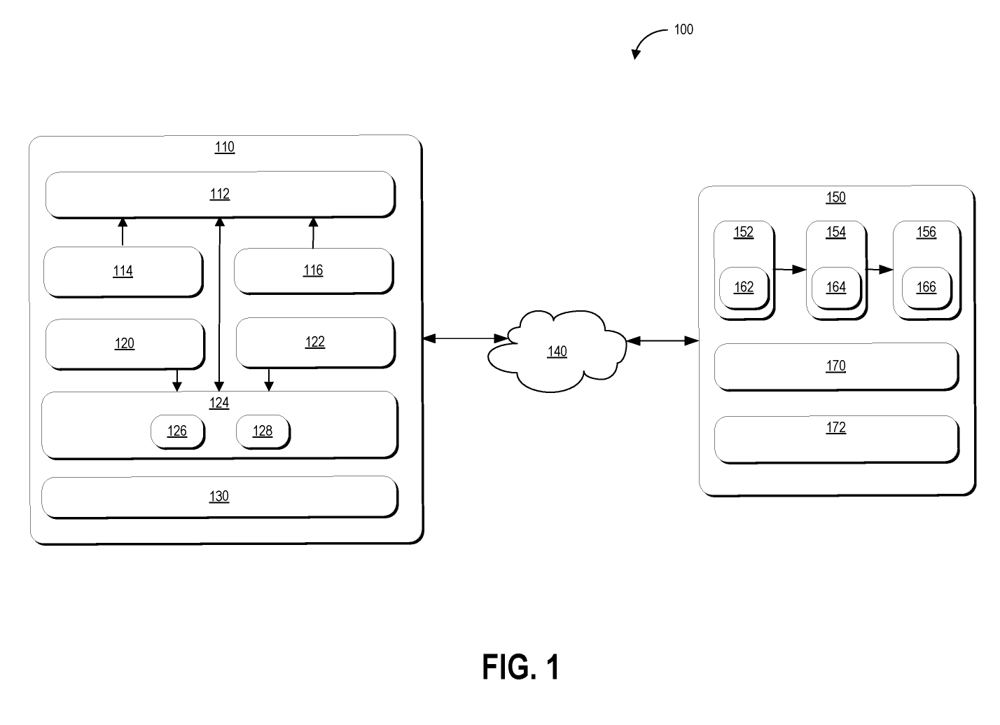

With reference now to FIGS. 1-8, example embodiments of the present disclosure will be discussed in further detail. FIG. 1 depicts an example of a system according to example embodiments of the present disclosure. The computing systems and computing devices in a computing system 100 can include various components for performing various operations and functions. For example, the computing systems and/or computing devices of the computing system 100 can include one or more processors and one or more tangible, non-transitory, computer readable media (e.g., memory devices, etc.). The one or more tangible, non-transitory, computer readable media can store instructions that when executed by the one or more processors cause the computing systems of the computing system 100 to perform operations and functions, such as those described herein for performing simulations including simulating sensor interactions (e.g., sensor interactions between sensors of a simulated autonomous vehicle and various simulated objects) in a simulated environment.

As illustrated in FIG. 1, the computing system 100 can include a simulation computing system 110; a sensor data renderer 112; a simulated object dynamics system 114; a simulated vehicle dynamics system 116; a scenario recorder 120; a scenario playback system 122; an memory 124; state data 126; motion trajectory data 128; a communication interface 130; one or more communication networks 140; an autonomy computing system 150; a perception system 152; a prediction system 154; a motion planning system 156; state data 162; prediction data 164; motion plan 166; and a communication interface 170.

The simulation computing system 110 can include a sensor data renderer 112 that is configured to render simulated sensor data associated with the simulated environment. The simulated sensor data can include various types based in part on simulated sensor outputs. For example, the simulated sensor data can include simulated image data, simulated Light Detection and Ranging (LIDAR) data, simulated Radio Detection and Ranging (RADAR) data, simulated sonar data, and/or simulated thermal imaging data. The simulated sensor data can be indicative of the state of one or more simulated objects in a simulated environment that can include a simulated autonomous vehicle. For example, the simulated sensor data can be indicative of one or more locations of the one or more simulated objects within the simulated environment at one or more times.

The simulation computing system 110 can exchange (e.g., send and/or receive) simulated sensor data to the autonomy computing system 150, via various networks including, for example, the one or more communication networks 140. Further, the autonomy computing system 150 can process the simulated sensor data associated with the simulated environment. For example, the autonomy computing system 150 can process the simulated sensor data in a manner that is the same as or similar to the manner in which an autonomous vehicle processes sensor data associated with an actual physical environment (e.g., a real-world environment). For example, the autonomy computing system 150 can be configured to process the simulated sensor data to detect one or more simulated objects in the simulated environment based at least in part on the simulated sensor data.

In some embodiments, the autonomy computing system 150 can predict the motion of the one or more simulated objects, as described herein. The autonomy computing system 150 can generate an appropriate motion plan 166 through the simulated environment, accordingly. As described herein, the autonomy computing system 150 can provide data indicative of the motion of the simulated autonomous vehicle to a simulation computing system 110 in order to control the simulated autonomous vehicle within the simulated environment.

The simulation computing system 110 can also include a simulated vehicle dynamics system 116 configured to control the dynamics of the simulated autonomous vehicle within the simulated environment. For example, in some embodiments, the simulated vehicle dynamics system 116 can control the simulated autonomous vehicle within the simulated environment based at least in part on the motion plan 166 determined by the autonomy computing system 150. The simulated vehicle dynamics system 116 can translate the motion plan 166 into instructions and control the simulated autonomous vehicle accordingly. In some embodiments, the simulated vehicle dynamics system 116 can control the simulated autonomous vehicle within the simulated environment based at least in part on instructions determined by the autonomy computing system 150 (e.g., a simulated vehicle controller). In some implementations, the simulated vehicle dynamics system 116 can be programmed to take into account certain dynamics of a vehicle. This can include, for example, processing delays, vehicle structural forces, travel surface friction, and/or other factors to provide an improved simulation of the implementation of a motion plan on an actual autonomous vehicle.

The simulation computing system 110 can include and/or otherwise communicate with other computing systems (e.g., the autonomy computing system 150) via the communication interface 130. The communication interface 130 can enable the simulation computing system 110 to receive data and/or information from a separate computing system such as, for example, the autonomy computing system 150. For example, the communication interface 130 can be configured to enable communication with one or more processors that implement and/or are designated for the autonomy computing system 150. The one or more processors in the autonomy computing system 150 can be different from the one or more processors that implement and/or are designated for the simulation computing system 110.

The simulation computing system 110 can obtain and/or receive, via the communication interface 130, an output (e.g., one or more signals and/or data) from the autonomy computing system 150. The output can include data associated with motion of the simulated autonomous vehicle. The motion of the simulated autonomous vehicle can be based at least in part on the motion of a simulated object, as described herein. For example, the output can be indicative of one or more command signals from the autonomy computing system 150. The one or more command signals can be indicative of the motion of the simulated autonomous vehicle. In some implementations, the one or more command signals can be based at least in part on the motion plan 166 generated by the autonomy computing system 150 for the simulated autonomous vehicle. The motion plan 166 can be based at least in part on the motion of the simulated object (e.g., to avoid colliding with the simulated object), as described herein. The one or more command signals can include instructions to implement the determined motion plan 166. In some implementations, the output can include data indicative of the motion plan 166 and the simulation computing system 110 can translate the motion plan 166 to control the motion of the simulated autonomous vehicle.

The simulation computing system 110 can control the motion of the simulated autonomous vehicle within the simulated environment based at least in part on the output from the autonomy computing system 150 that is obtained via the communication interface 130. For instance, the simulation computing system 110 can obtain, via the communication interface 130, the one or more command signals from the autonomy computing system 150. The simulation computing system 110 can model the motion of the simulated autonomous vehicle within the simulated environment based at least in part on the one or more command signals. In this way, the simulation computing system 110 can utilize the communication interface 130 to obtain data indicative of the motion of the simulated autonomous vehicle from the autonomy computing system 150 and control the simulated autonomous vehicle within the simulated environment, accordingly.

The simulation computing system 110 can include a scenario recorder 120 and a scenario playback system 122. The scenario recorder 120 can be configured to record data associated with one or more inputs and/or one or more outputs as well as data associated with a simulated object and/or the simulated environment before, during, and/or after the simulation is run. The scenario recorder 120 can provide data for storage in a memory 124 (e.g., a scenario memory). The memory 124 can be local to and/or remote from the simulation computing system 110. The scenario playback system 122 can be configured to retrieve data from the memory 124 for a future simulation. For example, the scenario playback system 122 can obtain data indicative of a simulated object (and its motion) in a first simulation for use in a subsequent simulation, as further described herein.

The simulation computing system 110 can store, in the memory 124, at least one of the state data 126 indicative of the one or more states of the simulated object and/or motion trajectory data 128 indicative of the motion trajectory of the simulated object within the simulated environment. The simulation computing system 110 can store the state data 126 and/or the motion trajectory data 128 indicative of the motion trajectory of the simulated object in various forms including a raw and/or parameterized form. The memory 124 (e.g., a scenario memory) can include one or more memory devices that are local to and/or remote from the simulation computing system 110. The memory can include a library database that includes state data 126 and/or motion trajectories of a plurality of simulated objects (e.g., generated based on user input) from a plurality of simulations (e.g., previously run simulations).

The state data 126 and/or the motion trajectory data 128 indicative of motion trajectories of simulated objects can be accessed, obtained, viewed, and/or selected for use in a subsequent simulation. For instance, the simulation computing system 110 can generate a second simulation environment for a second simulation. The second simulation environment can be similar to and/or different from a previous simulation environment (e.g., a similar or different simulated highway environment). The simulation computing system 110 can obtain (e.g., from the memory 124) the state data 126 indicative of the one or more states (e.g., in raw and/or parameterized form) of a simulated object and/or the motion trajectory data 128 indicative of a motion trajectory of the simulated object within the first simulated environment. The simulation computing system 110 can control a second motion of the simulated object within the second simulated environment based at least in part on the one or more states and/or the motion trajectory of the simulated object within the first simulated environment.

The simulation computing system 110 can be configured to generate a simulated environment and run a test simulation within that simulated environment. For instance, the simulation computing system 110 can obtain data indicative of one or more initial inputs associated with the simulated environment. For example, various characteristics of the simulated environment can be specified or indicated including: one or more sensor properties and/or characteristics for one or more simulated sensors in a simulated environment (e.g., various types of simulated sensors including simulated cameras, simulated LIDAR, simulated radar, and/or simulated sonar); a general geographic area for a simulated environment (e.g., general type of geographic area for the simulated environment (e.g., highway, urban, rural, etc.); a specific geographic area for the simulated environment (e.g., beltway of City A, downtown of City B, country side of County C, etc.); one or more geographic features (e.g., trees, benches, obstructions, buildings, boundaries, exit ramps, etc.) and their corresponding positions in the simulated environment; a time of day; one or more weather conditions; one or more initial conditions of the one or more simulated objects within the simulated environment (e.g., initial position, heading, speed, etc.); a type of each simulated object (e.g., vehicle, bicycle, pedestrian, etc.); a geometry of each simulated object (e.g., shape, size etc.); one or more initial conditions of the simulated autonomous vehicle within the simulated environment (e.g., initial position, heading, speed, etc.); a type of the simulated autonomous vehicle (e.g., sedan, sport utility, etc.); a geometry of the simulated autonomous vehicle (e.g., shape, size etc.); operating condition of each simulated object (e.g., correct turn signal usage vs. no turn signal usage, functional brake lights vs. one or more brake lights that are non-functional, etc.) and/or other data associated with the simulated environment.

In some implementations, the simulation computing system 110 can determine the initial inputs of a simulated environment without intervention or input by a user. For example, the simulation computing system 110 can determine one or more initial inputs based at least in part on one or more previous simulation runs, one or more simulated environments, one or more simulated objects, etc. The simulation computing system 110 can obtain the data indicative of the one or more initial inputs. The simulation computing system 110 can generate the simulated environment based at least in part on the data indicative of the one or more initial inputs.

The simulation computing system 110 can generate image data that can be used to generate a visual representation of a simulated environment via a user interface on one or more display devices (not shown). The simulated environment can include one or more simulated objects, simulated sensor interactions, and a simulated autonomous vehicle (e.g., as visual representations on the user interface).

The simulation computing system 110 can communicate (e.g., exchange one or more signals and/or data) with the one or more computing devices including the autonomy computing system 150, via one or more communications networks including the one or more communication networks 140. The one or more communication networks 140 can exchange (send or receive) signals (e.g., electronic signals) or data (e.g., data from a computing device) and include any combination of various wired (e.g., twisted pair cable) and/or wireless communication mechanisms (e.g., cellular, wireless, satellite, microwave, and radio frequency) and/or any desired network topology (or topologies). For example, the one or more communication networks 140 can include a local area network (e.g. intranet), wide area network (e.g. Internet), wireless LAN network (e.g., via Wi-Fi), cellular network, a SATCOM network, VHF network, a HF network, a WiMAX based network, and/or any other suitable communications network (or combination thereof) for transmitting data between the autonomy computing system 150 and the simulation computing system 110.

As depicted in FIG. 1, the autonomy computing system 150 can include a perception system 152, a prediction system 154, a motion planning system 156, and/or other systems that can cooperate to determine the state of a simulated environment associated with the simulated vehicle and determine a motion plan for controlling the motion of the simulated vehicle accordingly. For example, the autonomy computing system 150 can receive the simulated sensor data from the simulation computing system 110, attempt to determine the state of the surrounding environment by performing various processing techniques on the data (e.g., simulated sensor data) received from the simulation computing system 110, and generate a motion plan through the surrounding environment. In some embodiments, the autonomy computing system 150 can control the one or more simulated vehicle control systems 172 to generate motion data associated with a simulated vehicle according to the motion plan 156.

The autonomy computing system 150 can identify one or more objects in the simulated environment (e.g., one or more objects that are proximate to the simulated vehicle) based at least in part on the data including the simulated sensor data from the simulation computing system 110. For example, the perception system 152 can obtain state data 162 descriptive of a current and/or past state of one or more objects including one or more objects proximate to a simulated vehicle.

The state data 162 for each object can include or be associated with state data and/or state information including, for example, an estimate of the object's current and/or past location and/or position; an object's motion characteristics including the object's speed, velocity, and/or acceleration; an object's heading and/or orientation; an object's physical dimensions (e.g., an object's height, width, and/or depth); an object's texture; a bounding shape associated with the object; and/or an object class (e.g., building class, sensor class, pedestrian class, vehicle class, and/or cyclist class). Further, the perception system 152 can provide the state data 162 to the prediction system 154 (e.g., to predict the motion and movement path of an object).

The prediction system 154 can generate prediction data 164 associated with each of the respective one or more objects proximate to a simulated vehicle. The prediction data 164 can be indicative of one or more predicted future locations of each respective object. The prediction data 164 can be indicative of a predicted path (e.g., predicted trajectory) of at least one object within the surrounding environment of a simulated vehicle. For example, the predicted path (e.g., trajectory) can indicate a path along which the respective object is predicted to travel over time (and/or the velocity at which the object is predicted to travel along the predicted path). The prediction system 154 can provide the prediction data 164 associated with the one or more objects to the motion planning system 156.

The motion planning system 156 can determine and generate a motion plan 166 for the simulated vehicle based at least in part on the prediction data 164 (and/or other data). The motion plan 166 can include vehicle actions with respect to the objects proximate to the simulated vehicle as well as the predicted movements. For instance, the motion planning system 156 can implement an optimization algorithm that considers cost data associated with a vehicle action as well as other objective functions (e.g., cost functions based on speed limits, traffic lights, and/or other aspects of the environment), if any, to determine optimized variables that make up the motion plan 166. By way of example, the motion planning system 156 can determine that a simulated vehicle can perform a certain action (e.g., passing a simulated object) with a decreased probability of intersecting and/or contacting the simulated object and/or violating any traffic laws (e.g., speed limits, lane boundaries, and/or driving prohibitions indicated by signage). The motion plan 166 can include a planned trajectory, velocity, acceleration, and/or other actions of the simulated vehicle.

The motion planning system 156 can provide data indicative of the motion plan 166 with data indicative of the vehicle actions, a planned trajectory, and/or other operating parameters to the vehicle control systems 172 to implement the motion plan 166 for the simulated vehicle. For instance, the simulated vehicle can include a mobility controller configured to translate the motion plan 166 into instructions. By way of example, the mobility controller can translate a determined motion plan 166 into instructions for controlling the simulated vehicle including adjusting the steering of the simulated vehicle “X” degrees and/or applying a certain magnitude of braking force. The mobility controller can send one or more control signals to the responsible vehicle control component (e.g., braking control system, steering control system and/or acceleration control system) to execute the instructions and implement the motion plan 166.

The autonomy computing system 150 can include a communication interface 170 configured to enable the autonomy computing system 150 (and its one or more computing devices) to exchange (e.g., send or receive one or more signals and/or data) with other computing devices including, for example, the simulation computing system 110. The autonomy computing system 150 can use the communication interface 170 to communicate with one or more computing devices (e.g., the simulation computing system 110) over one or more networks (e.g., via one or more wireless signal connections), including the one or more communication networks 140. The communication interface 170 can utilize various communication technologies including, for example, radio frequency signaling and/or Bluetooth low energy protocol. The communication interface 170 can include any suitable components for interfacing with one or more networks, including, for example, one or more: transmitters, receivers, ports, controllers, antennas, and/or other suitable components that can help facilitate communication. The communication interface 170 can include a plurality of components (e.g., antennas, transmitters, and/or receivers.) that allow it to implement and utilize multiple-input, multiple-output (MIMO) technology and communication techniques.

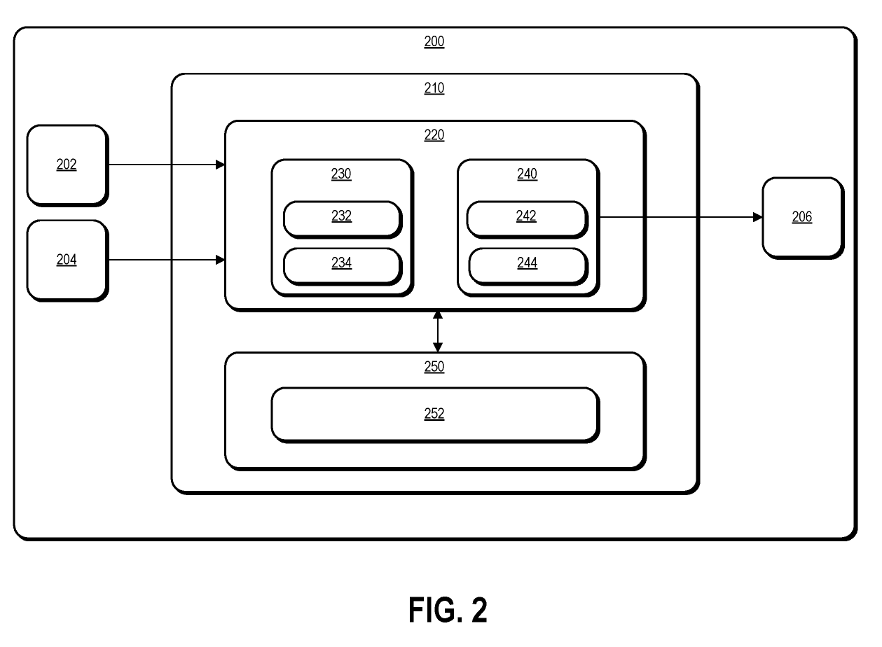

FIG. 2 depicts an example of a sensor testing and optimization system according to example embodiments of the present disclosure. As illustrated, a sensor testing system 200, can include one or more features, components, and/or devices of the computing system 100 depicted in FIG. 1, and further can include simulated object data 202; static background data 204; a computing device 206; a computing device 210 which can include one or more features, components, and/or devices of the simulation computing system 110 depicted in FIG. 1; a scene 220; one or more simulated objects 230; an object 232; an object 234; one or more simulated sensor objects 240; a sensor object 242; a sensor object 244; a rendering interface 250; and a rendering device 252.

The sensor testing system 200 can include one or more computing devices (e.g., the computing device 210), which can include one or more processors (not shown), one or more memory devices (not shown), and one or more communication interfaces (not shown). The computing device 210 can be configured to process, generate, receive, send, and/or store one or more signals or data including one or more signals or data associated with a simulated environment that can include one or more simulated objects. For example, the computing device 210 can receive the simulated object data 202 which can include virtual object data that can include states and/or properties (e.g., velocity, acceleration, physical dimensions, trajectory, and/or travel path) associated with one or more simulated objects and/or virtual objects.

For example, the simulated object data 202 can include data associated with the states and/or properties of one or more dynamic simulated objects (e.g., simulated sensors, simulated vehicles, simulated pedestrians, and/or simulated cyclists) in a scene (e.g., the scene 220) including a simulated environment. The one or more dynamic simulated objects 230 can include one or more objects with states and/or properties (e.g., location, velocity, and/or path) that change when a simulation is run. For example, the one or more dynamic simulated objects 230 can include one or more simulated vehicle objects that are programmed and/or configured to change location as a simulation, which can include one or more scenes including the scene 220, is run.

The computing device 210 can also receive the static background data 204 which can include data associated with the states and/or properties of one or more static simulated objects (e.g., simulated buildings, simulated tunnels, and/or simulated bridges) in a scene (e.g., the scene 220) including a simulated environment. The one or more static simulated objects can include one or more objects with states and/or properties (e.g., location, velocity, and/or path) that do not change during when a simulation is run. For example, the one or more static simulated objects 240 can include one or more simulated building objects that are programmed and/or configured to remain in the same location as a simulation, which can include one or more scenes including the scene 220, is run.

The scene 220 can include and/or be associated with data for a simulated environment that includes one or more simulated objects 230 that can include the object 232 (e.g., a vehicle) and the object 234 (e.g., a cyclist) and can interact with one or more other objects in the simulated environment. The one or more simulated objects 230 can include simulated objects that include various states and/or properties including simulated objects that are solid (e.g., vehicles, buildings, and/or pedestrians) and simulated objects that are non-solid (e.g., light rays, light beams, and/or sound waves). Further, the scene 220 can include one or more simulated sensor objects 240 which can include the sensor object 242 (e.g., a LIDAR sensor object) and the sensor object 244 (e.g., an image sensor object).

The one or more simulated objects 230 and the one or more simulated sensor objects 240 can be used to generate one or more sensor interactions from which sensor data can be generated and used as an output for the scene 220. In some embodiments, data including the states and/or properties of the one or more simulated objects 230 and the one or more simulated sensor objects 240 can be sent (e.g., sent via one or more interconnects or networks (not shown)) to the rendering interface 250 which can be used to exchange (e.g., send and/or receive) the data from the scene 220.

The rendering interface 250 can be associated with the rendering device 252 (e.g., a device or process that performs one or more rendering techniques, including ray tracing, and which can render one or more images based in part on the states and/or properties of the one or more simulated objects 230 and/or the one or more simulated sensor objects 240 in the scene 220). Further, the rendering device 252 can generate an image or a plurality of images using one or more techniques including ray tracing, ray casting, recursive casting, and/or photon mapping. In some embodiments, the image or plurality of images generated by the rendering device 252 can be used to generate the one or more sensor interactions from which sensor data can be generated and used as an output for the scene 220. Accordingly, the output of the scene 220 can include one or more signals or data including sensor data (e.g., one or more sensor data packets) that can be sent from the computing device 210 to another device including the computing device 206 which can perform one or more operations on the sensor data (e.g., operating an autonomous vehicle).

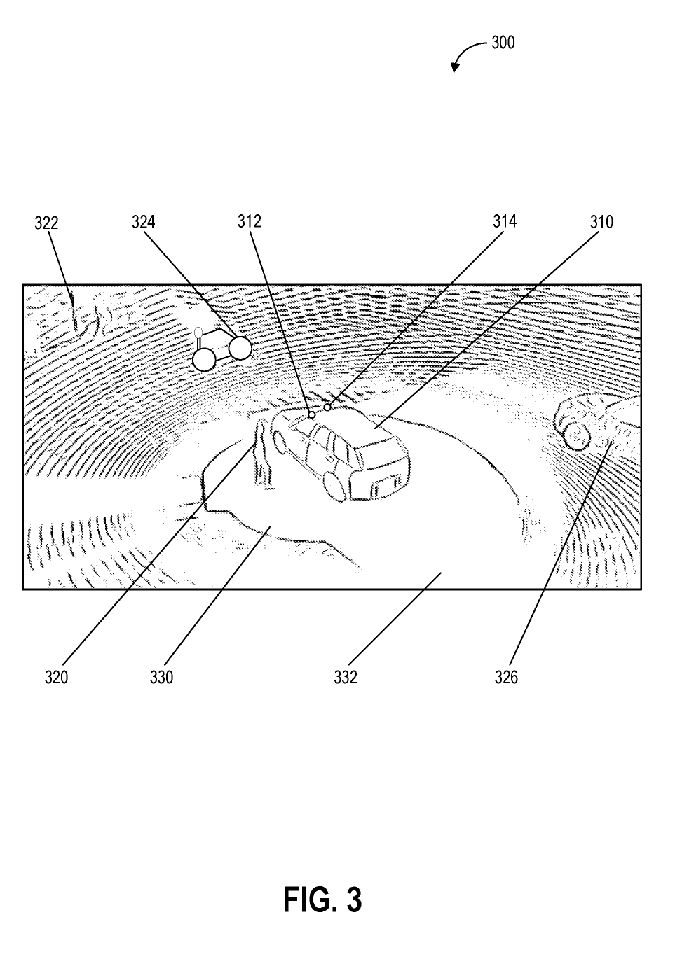

FIG. 3 depicts an example of a scene generated by computing system according to example embodiments of the present disclosure. The output from a simulated sensor system can be based in part on obtaining, receiving, generating, and/or processing of one or more portions of a simulated environment by one or more devices (e.g., one or more computing devices) or systems including, for example, one or more devices or systems of the system 100, shown in FIG. 1. Moreover, the receiving, generating, and/or processing of one or more portions of a simulated environment can be implemented as an algorithm on the hardware components of one or more devices or systems (e.g., the simulation computing system 110 and/or the autonomy computing system 150, shown in FIG. 1) to, for example, obtain a simulated scene and generate sensor data including simulated sensor interactions in the scene.

As illustrated, FIG. 3 shows a scene 300; a simulated object 310; a simulated object 312; a simulated object 314; a simulated object 320; a simulated object 322; a simulated object 324; a simulated object 326; a simulated sensor interaction area 330 (e.g., a simulated area with high sensor noise); and a simulated sensor interaction area 332 (e.g., a simulated area without sensor coverage).

In this example, the scene 300 (e.g., a simulated environment which can be represented as one or more data objects or images) includes one or more simulated objects including the simulated object 310 (e.g., a simulated autonomous vehicle), the simulated object 312 (e.g., a simulated sensor positioned at a corner of the simulated autonomous vehicle's roof), the simulated object 314 (e.g., a simulated sensor positioned at an edge of the simulated autonomous vehicle's windshield), the simulated object 320 (e.g., a simulated pedestrian), the simulated object 322 (e.g., a simulated lamppost), the simulated object 324 (e.g., a simulated cyclist), and the simulated object 326 (e.g., a simulated vehicle). Further, the scene 300 includes a representation of one or more simulated sensor interactions including the simulated sensor interaction area 330 (e.g., a simulated area with high sensor noise) and the simulated sensor interaction area 332 (e.g., a simulated area without sensor coverage).

As shown in FIG. 3, the scene 300 can include one or more simulated objects, of which the properties and/or states (e.g., physical dimensions, velocity, and/or travel path) can be used to generate and/or determine one or more simulated sensor interactions. For example, a simulated pulsed laser from one or more simulated LIDAR devices can interact with one or more of the simulated objects and can be used to determine one or more sensor interactions between the one or more simulated LIDAR devices and the one or more simulated objects.

A plurality of scenes can be generated, with each scene including a different set of simulated sensor interactions based on different sets of the simulated objects (e.g., different vehicles, pedestrians, and/or buildings), states and/or properties of the simulated objects (e.g., different sensor properties corresponding to different sensor types and/or different object velocities, positions, and/or paths), which can be analyzed in order to determine more optimal configurations or calibrations for one or more actual sensors.

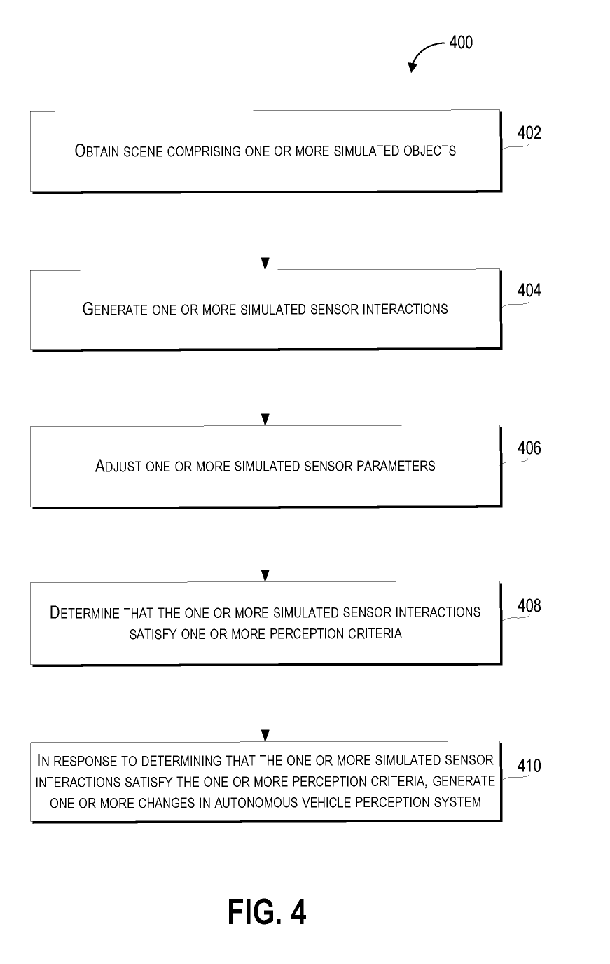

FIG. 4 depicts a flow diagram of an example method of sensor testing and optimization according to example embodiments of the present disclosure. One or more portions of a method 400, illustrated in FIG. 4, can be implemented by one or more devices (e.g., one or more computing devices) or systems including, for example, one or more devices or systems of the computing system 100, shown in FIG. 1. Moreover, one or more portions of the method 400 can be implemented as an algorithm on the hardware components of the devices described herein (e.g., as in FIG. 1) to, for example, generate sensor data based in part on a simulated scene including simulated objects associated with simulated physical properties. FIG. 4 depicts elements performed in a particular order for purposes of illustration and discussion. Those of ordinary skill in the art, using the disclosures provided herein, will understand that the elements of any of the methods discussed herein can be adapted, rearranged, expanded, omitted, combined, and/or modified in various ways without deviating from the scope of the present disclosure.

At 402, the method 400 can include obtaining a scene including one or more simulated objects associated with one or more simulated physical properties. For example, the simulation computing system 110 can obtain data (e.g., the state data 126 and/or the motion trajectory data 128) including a scene that includes one or more simulated objects associated with one or more simulated physical properties. For example, a scene (e.g. a scene can include data structure associated with other data structures including the one or more simulated objects and the one or more simulated physical properties) can be obtained from a computing system, computing device, or storage device via one or more networks (e.g., the one or more communications networks 140). Further, the one or more simulated objects can be associated with one or more simulated physical properties associated with a location (e.g., a set of three-dimensional coordinates associated with the one or more locations of the one or more simulated objects within the scene), a velocity, an acceleration, spatial dimensions (e.g., a three-dimensional mesh of the one or more simulated objects), a mass, a color, a reflectivity, a reflectance, and/or a path (e.g., a set of locations that the one or more simulated objects will traverse and/or a corresponding set of times that the one or more simulated objects will be at the set of locations) of the one or more simulated objects.

At 404, the method 400 can include generating sensor data including one or more simulated sensor interactions for the scene. For example, the simulation computing system 110 can generate data (e.g., the sensor data) using the sensor data renderer 112. The one or more simulated sensor interactions can include one or more simulated sensors detecting the one or more simulated objects. Further, the one or more simulated sensors can include one or more simulated sensor properties.

In some embodiments, the one or more simulated sensors can include a spinning sensor having a detection capability that can be based in part on a simulated relative velocity distortion associated with a spin rate of the spinning sensor and a velocity of the one or more objects relative to the spinning sensor. For example, a simulated spinning sensor can be configured to simulate a greater level of sensor distortion as the spin rate decreases or the velocity of the one or more objects relative to the simulated spinning sensor increase.

In some embodiments, the one or more simulated sensor properties can be based at least in part on one or more sensor properties of one or more physical sensors including one or more light detection and ranging devices (LIDAR), one or more radar devices, one or more sonar devices, and/or one or more cameras. Further, the specifications and performance characteristics of one or more physical sensors can be determined based on one or more sensor interactions of the one or more physical sensors with one or more physical objects. For example, the sensitivity of a physical sensor can be determined by testing the physical sensor in a variety of different environmental conditions (e.g., different temperatures, different humidity, and/or different levels of sunlight) and the determined sensitivity of the physical sensor can be used as the basis for a simulated sensor.

In some embodiments, the one or more simulated sensor properties of the one or more simulated sensors can include a spin rate, a point density (e.g., a density of the three dimensional points in an image captured by a simulated sensor), a field of view (e.g., an angular field of view of a sensor), a height (e.g., a height of a simulated sensor with respect to a simulated ground object), a frequency (e.g., a frequency with which a simulated sensor detects and/or interacts with one or more simulated objects), an amplitude, a focal length (e.g., a focal length of a simulated lens), a range (e.g., a maximum distance a simulated sensor can detect one or more simulated objects and/or a set of ranges at which a simulated sensor can detect one or more simulated objects with a varying level of accuracy), a sensitivity (e.g., the smallest change in the state of one or more simulated objects that will result in a simulated sensor output by a simulated sensor), a latency (e.g., a latency time period between a simulated sensor detecting one or more simulated objects and generating a simulated sensor output), a linearity, and/or a resolution (e.g., the smallest change in the state of one or more simulated objects that a simulated sensor can detect).

In some embodiments, the one or more simulated sensor interactions can include one or more obfuscating interactions that reduce detection capabilities of the one or more simulated sensors. The one or more obfuscating interactions can include sensor cross-talk, sensor noise, sensor blooming, spinning sensor distortion (e.g., distortion caused by the location and/or position of a spinning sensor changing as the spinning sensor spins), sensor lens distortion, sensor tangential distortion (e.g., an optical aberration caused by a non-parallel simulated lens and simulated sensor), sensor banding, or color imbalance (e.g., distortions in the intensities of colors captured by simulated image sensors).

In some embodiments, the one or more simulated sensor interactions can include one or more sensor miscalibration interactions associated with inaccurate placement (e.g., an inaccurate or erroneous position, location and/or angle) of the one or more simulated sensors that reduces detection accuracy of the one or more simulated sensors. The one or more sensor miscalibration interactions can include inaccurate sensor outputs from the one or more simulated sensors caused by the inaccurate placement (e.g., misplacement) of the one or more simulated sensors.

For example, the one or more simulated sensors can be positioned (e.g., positioned on a simulated vehicle) according to a set of sensor coordinates including an x-coordinate position, a y-coordinate position, and a z-coordinate position of the one or more simulated sensors with respect to a ground plane or a vehicle (e.g., a vehicle on which the one or more simulated sensors are mounted) of the scene; and/or an angle of the one or more simulated sensors with respect to the ground plane or a vehicle (e.g., a vehicle on which the one or more simulated sensors are mounted) of the scene. The one or more sensor miscalibration interactions can include one or more sensor outputs of the one or more simulated sensors that are inaccurate (e.g., erroneous) due to one or more inaccuracies and/or errors in the position, location, and/or angle of the one or more simulated sensors (e.g., a simulated sensor provides sensor outputs for a sensor position that is two centimeters higher than the position of the simulated sensor and/or a simulated sensor provides sensor outputs for a sensor angle position that is two degrees lower than the position of the simulated sensor). In this way, the sensitivity of an autonomous vehicle's systems to the one or more sensor miscalibration interactions can be more effectively tested.

At 406, the method 400 can include adjusting the one or more simulated sensor properties of the one or more simulated sensors based at least in part on the one or more obfuscating interactions that reduce the detection capabilities of the one or more simulated sensors. For example, the simulation computing system 110 can adjust the one or more simulated sensor properties of the one or more simulated sensors based at least in part on the one or more obfuscating interactions that reduce the detection capabilities of the one or more simulated sensors. The one or more obfuscating interactions can simulate physical obfuscating interactions that can result from the interaction between the one or more simulated sensors and the one or more simulated objects in the scene (e.g., other simulated sensors, simulated pedestrians, simulated street lights, simulated sunlight, simulated rain, simulated fog, simulated bodies of water, and/or simulated reflective surfaces including mirrors).

The simulation computing system 110 can adjust the one or more simulated sensor properties of the one or more simulated sensors that are changeable to counteract the effects of the one or more obfuscating interactions (e.g., changing the angle of an image sensor with respect to other sensors). For example, the simulation computing system 110 can exchange (e.g., send and/or receive) one or more control signals to adjust the one or more simulated properties of the one or more simulated sensors that are changeable. Accordingly, based on the adjustment to the one or more simulated sensor properties of the one or more simulated sensors, one or more physical sensors upon which the one or more simulated sensor properties are based can be adjusted in a similar way (e.g., a physical image sensor can be adjusted in accordance with the changes in the angle of the simulated image sensor).

In some embodiments, the simulation computing system 110 can adjust the one or more simulated sensor properties of the one or more simulated sensors based at least in part on the one or more sensor miscalibration interactions associated with inaccurate placement of the one or more simulated sensors. For example, when the one or more sensor interactions include one or more sensor miscalibration interactions associated with a miscalibrated simulated camera sensor with a position that is five degrees to the right of the correct position. The simulation computing system 110 can adjust the one or more simulated properties of the one or more simulated sensors including adjusting the angle of a set (e.g., a set not including the miscalibrated simulated camera sensor) of the one or more simulated sensors to compensate for the incorrect position of the miscalibrated simulated camera sensor.

At 408, the method 400 can include determining, based in part on the sensor data, that the one or more simulated sensor interactions satisfy one or more perception criteria including one or more perception criteria of an autonomous vehicle perception system. For example, the simulation computing system 110 can determine, based in part on the sensor data (e.g., data including data generated by the sensor data renderer 112) us the one or more simulated sensor interactions that satisfy one or more perception criteria including one or more perception criteria of an autonomous vehicle perception system (e.g., the perception system 152 of the autonomy computing system 150).

The one or more perception criteria can be based in part on characteristics of the one or more simulated sensor interactions including, for example, one or more thresholds (e.g., maximum or minimum values) associated with the one or more simulated sensor properties including a range of the one or more simulated sensors, an accuracy of the one or more simulated sensors, a precision of the one or more simulated sensors, and/or the sensitivity of the one or more simulated sensors. Satisfaction of the one or more perception criteria can be based in part on a comparison of various aspects of the sensor data to one or more corresponding perception criteria values. For example, the one or more simulated sensor interactions can be compared to a minimum sensor range threshold, and the one or more simulated sensor interactions that satisfy the one or more perception criteria can include the one or more simulated sensor interactions that exceed the minimum sensor range threshold.

At 410, the method 400 can include, in response to determining that the one or more simulated sensor interactions satisfy the one or more perception criteria, generating, based in part on the one or more simulated sensor interactions that satisfy the one or more perception criteria, one or more changes for (or to) the autonomous vehicle perception system. For example, the simulation computing system 110 can generate, based in part on the one or more simulated sensor interactions that satisfy the one or more perception criteria, one or more changes for (or to) the autonomous vehicle perception system (e.g., the perception system 152 of the autonomy computing system 150). For example, in an autonomous vehicle with three sensors, the one or more simulated sensor interactions can indicate that a first simulated sensor has superior accuracy to a second simulated sensor and a third simulated sensor in certain scenes (e.g., the first simulated sensor may have greater accuracy in a scene that is cloudless and includes intense sunlight) and can generate one or more changes in the autonomous vehicle perception system (e.g., weighing the autonomous vehicle perception system to use more sensor data from the first sensor when the intensity of sunlight exceeds a threshold intensity level). Further, in some embodiments, the one or more changes to the autonomous vehicle perception system can be performed via the modification of data in the autonomous vehicle perception system that is associated with the operation and/or configuration of one or more sensors of an autonomous vehicle (e.g., modifying data structures that indicate an angle of one or more image sensors in the autonomous vehicle).

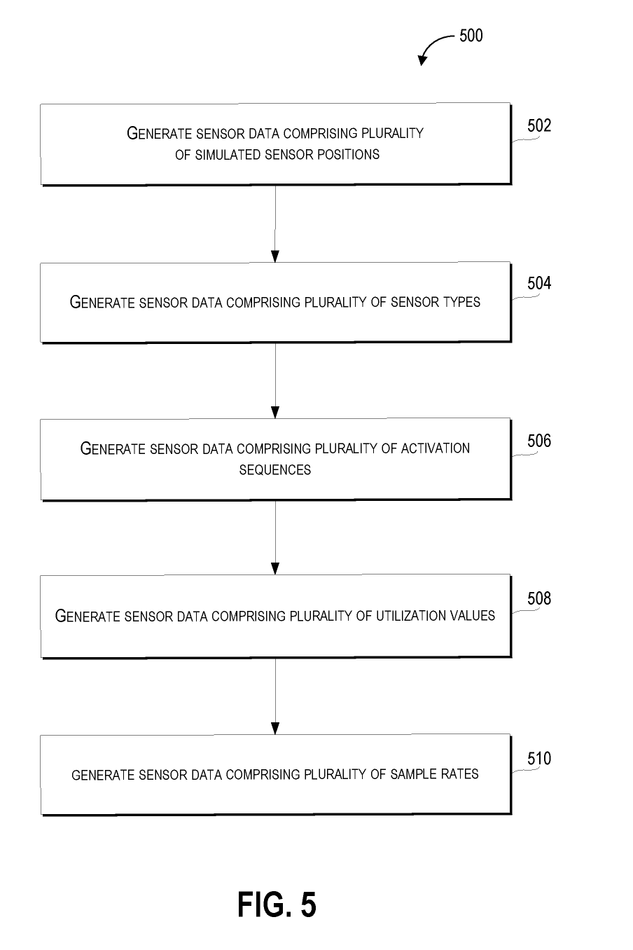

FIG. 5 depicts a flow diagram of an example method of sensor testing and optimization according to example embodiments of the present disclosure. One or more portions of a method 500, illustrated in FIG. 5, can be implemented by one or more devices (e.g., one or more computing devices) or systems including, for example, one or more devices or systems of the computing system 100, shown in FIG. 1. Moreover, one or more portions of the method 500 can be implemented as an algorithm on the hardware components of the devices described herein (e.g., as in FIG. 1) to, for example, generate sensor data based in part on a simulated scene including simulated objects associated with simulated physical properties. FIG. 5 depicts elements performed in a particular order for purposes of illustration and discussion. Those of ordinary skill in the art, using the disclosures provided herein, will understand that the elements of any of the methods discussed herein can be adapted, rearranged, expanded, omitted, combined, and/or modified in various ways without deviating from the scope of the present disclosure.

At 502, the method 500 can include generating sensor data (e.g., the sensor data of the method 400) based at least in part on a detection, by the one or more simulated sensors, of the one or more simulated objects (e.g., the one or more simulated sensors detecting the one or more simulated objects) from a plurality of simulated sensor positions within the scene. For example, the simulation computing system 110 including the sensor data renderer 112 (e.g., using data received from the simulated object dynamics system 114 and/or the simulated vehicle dynamics system 116) can generate the sensor data based at least in part on a detection, by the one or more simulated sensors, of the one or more simulated objects from a plurality of simulated sensor positions within the scene.

Each of the plurality of simulated sensor positions can include a set of sensor coordinates including an x-coordinate position, a y-coordinate position, and a z-coordinate position of the one or more simulated sensors with respect to a ground plane of the scene; and/or an angle of the one or more simulated sensors with respect to the ground plane of the scene. For example, the sensor data can be based in part on the one or more simulated sensor interactions of the one or more sensors at various heights or at various angles with respect to a ground plane of the scene or a surface of a simulated autonomous vehicle. The one or more simulated sensor interactions can be based at least in part on the detection of the one or more simulated objects from the plurality of simulated sensor positions within the scene.

At 504, the method 500 can include generating the sensor data based at least in part on a detection, by the one or more simulated sensors, of the one or more simulated objects using a plurality of simulated sensor types. For example, the simulation computing system 110 including the sensor data renderer 112 (e.g., using data received from the simulated object dynamics system 114 and/or the simulated vehicle dynamics system 116) can generate the sensor data based at least in part on a detection, by the one or more simulated sensors, of the one or more simulated objects using a plurality of simulated sensor types (e.g., data including simulated sensor type data associated with a data structure including different simulated sensor type properties and/or parameters).

For each of the plurality of simulated sensor types, the one or more simulated sensor properties, or values associated with the one or more simulated sensor properties can be different. For example, a simulated audio sensor (e.g., a simulated microphone) can detect simulated sounds produced by a simulated object but can be configured not to detect the brightness of simulated sunshine. In contrast a simulated image sensor can detect the simulated sunshine but can be configured not to detect the simulated sounds produced by the simulated objects. In some embodiments, the one or more simulated sensor interactions can be based at least in part on the detection of the one or more simulated objects using the plurality of simulated sensor types.

At 506, the method 500 can include generating the sensor data based at least in part on a detection, by one or more simulated sensors, of the one or more simulated objects using a plurality of activation sequences. For example, the simulation computing system 110 including the sensor data renderer 112 (e.g., using data received from the simulated object dynamics system 114 and/or the simulated vehicle dynamics system 116) can generate the sensor data based at least in part on a detection, by the one or more simulated sensors, of the one or more simulated objects using a plurality of activation sequences. (e.g., data including simulated activation sequence data associated with a data structure including different simulated orders and/or activation sequences for one or more simulated sensors).

The plurality of activation sequences can include an order and a timing of activating the one or more simulated sensors. The plurality of activation sequences can include an order, timing, and/or sequence of activating the one or more simulated sensors. As the sequence in which the one or more simulated sensors is activated can be configured to effect the way in which other simulated sensors detect the simulated objects (e.g., interference), the one or more simulated sensor interactions can change based on the sequence in which the sensors are activated, and/or the time interval between activating different sensors. For example, a simulated sensor that is configured to produce distortion in other simulated sensors can be activated last (e.g., after the other sensors), so as to minimize its distorting effect on the other sensors. In some embodiments, the one or more simulated sensor interactions can be based at least in part on the detection of the one or more simulated objects in the plurality of activation sequences.

At 508, the method 500 can include generating the sensor data based at least in part on a detection, by the one or more simulated sensors, of the one or more simulated objects based in part on a plurality of utilization levels associated with a number of the one or more simulated sensors that are activated at a time. For example, the simulation computing system 110 including the sensor data renderer 112 (e.g., using data received from the simulated object dynamics system 114 and/or the simulated vehicle dynamics system 116) can generate the sensor data based at least in part on a detection, by the one or more simulated sensors, of the one or more simulated objects based in part on a plurality of utilization levels associated with a number of the one or more simulated sensors that are activated at a time (e.g., data including simulated utilization level data associated with a data structure including different sensor utilization levels for one or more simulated sensors).

For example, the one or more simulated sensor interactions can include one or more sensor interactions for various numbers of the one or more simulated sensors (e.g., one sensor, six sensors, and/or ten sensors). The different number of sensors in the one or more sensor interactions can generate different combinations of the one or more simulated sensor outputs that can provide a different indication of the state of the scene (e.g., more sensors can result in greater coverage of an area). In some embodiments, the one or more simulated sensor interactions can be based at least in part on the detection of the one or more simulated objects based in part on the plurality of utilization levels.

At 510, the method 500 can include generating the sensor data based at least in part on a detection, by the one or more simulated sensors, of the one or more simulated objects (e.g., the one or more simulated sensors detecting the one or more simulated objects) using a plurality of sample rates associated with a frequency with which the one or more simulated sensors detect the one or more simulated objects. For example, the simulation computing system 110 including the sensor data renderer 112 (e.g., using data received from the simulated object dynamics system 114 and/or the simulated vehicle dynamics system 116) can generate the sensor data based at least in part on a detection, by the one or more simulated sensors, of the one or more simulated objects using a plurality of sample rates (e.g., data structures for the one or more simulated sensors including a sample rate property and/or parameter) associated with a frequency with which the one or more simulated sensors detect the one or more simulated objects. For example, each of the plurality of sample rates can be associated with a frequency (e.g., a sampling rate of a microphone) at which the one or more simulated sensors generate the simulated sensor output. In some embodiments, the one or more simulated sensor interactions can be based in part on the detection of the one or more simulated objects using the plurality of sample rates.

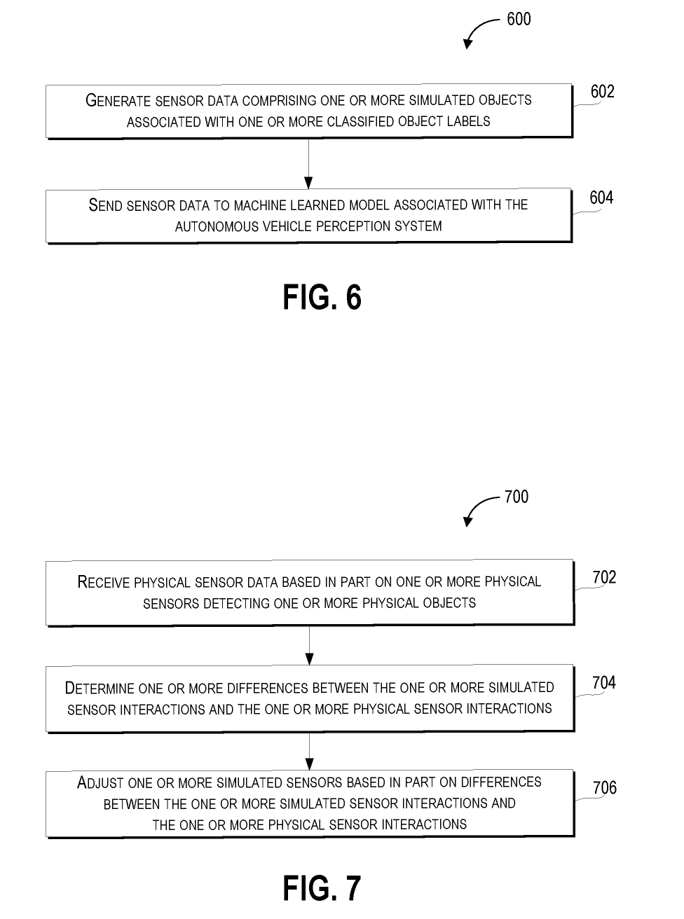

FIG. 6 depicts a flow diagram of an example method of sensor testing and optimization according to example embodiments of the present disclosure. One or more portions of a method 600, illustrated in FIG. 6, can be implemented by one or more devices (e.g., one or more computing devices) or systems including, for example, one or more devices or systems of the computing system 100, shown in FIG. 1. Moreover, one or more portions of the method 600 can be implemented as an algorithm on the hardware components of the devices described herein (e.g., as in FIG. 1) to, for example, generate sensor data based in part on a simulated scene including simulated objects associated with simulated physical properties. FIG. 6 depicts elements performed in a particular order for purposes of illustration and discussion. Those of ordinary skill in the art, using the disclosures provided herein, will understand that the elements of any of the methods discussed herein can be adapted, rearranged, expanded, omitted, combined, and/or modified in various ways without deviating from the scope of the present disclosure.

At 602, the method 600 can include associating one or more simulated objects of the sensor data (e.g., the one or more simulated objects and the sensor data of the method 400) with one or more classified object labels. For example, the computing system 810 and/or the machine-learning computing system 850 can associate data associated with the one or more simulated objects with one or more classified object labels. For example, the one or more simulated objects can be associated with one or more data structures that include one or more classified object labels. For example, one or more simulated pedestrian objects can be associated with one or more classified object labels that identify or classify the one or more simulated pedestrian objects as pedestrians, vehicles, bicycles, etc.

At 604, the method 600 can include sending the sensor data (e.g., the sensor data comprising the one or more simulated objects associated with the one or more classified object labels) to a machine-learned model (e.g., a machine-learned model associated with the autonomous vehicle perception system). As such, the sensor data can be used to train the machine-learned model. For example, a machine-learned model (e.g., the one or more machine-learned models 830 and/or the one or more machine-learned models 870) can receive input (e.g., sensor data) from one or more computing systems including the computing system 810. Further, the machine-learned model can generate classified object labels based on the sensor data. In some embodiments, the classified object labels associated with the one or more simulated objects can be generated in the same format as the classified object labels generated by the machine-learned model.

For example, the simulation computing system 110 can include, employ, and/or otherwise leverage a machine-learned object detection and prediction model. The machine-learned object detection and prediction model can be or can otherwise include one or more various models such as, for example, neural networks (e.g., deep neural networks), or other multi-layer non-linear models.

Neural networks can include convolutional neural networks, recurrent neural networks (e.g., long short-term memory recurrent neural networks), feed-forward neural networks, and/or other forms of neural networks. For instance, supervised training techniques can be performed to train the machine-learned object detection and prediction model to detect and/or predict an interaction between: the one or more simulated sensors (e.g., the one or more simulated sensors generated by the sensor data renderer 112); the one or more simulated sensors (e.g., the one or more simulated sensors generated by the sensor data renderer 112) and one or more simulated objects; and/or the one or more simulated objects. In some implementations, training data for the machine-learned object detection and prediction model can be based at least in part on the predicted interaction outcomes determined using a rules-based model, that can be used to help train the machine-learned object detection and prediction model to detect and/or predict one or more interactions associated with the one or more simulated sensors and the one or more simulated objects. Further, the training data can be used to train the machine-learned object detection and prediction model offline.

In some embodiments, the simulation computing system 110 can input data into the machine-learned object detection and prediction model and receive an output. For instance, the simulation computing system 110 can obtain data indicative of a machine-learned object detection and prediction model from an accessible memory (e.g., the memory 854) associated with the machine learning computing system 850. The simulation computing system 110 can provide input data into the machine-learned object detection and prediction model. The input data can include the data associated with the one or more simulated sensors and the one or more simulated objects including one or more simulated vehicles, pedestrians, cyclists, buildings, and/or environments associated with the one or more objects (e.g., roads, bodies of water, and/or forests). Further, the input data can include data indicative of the one or more simulated sensors (e.g., the properties of the one or more simulated sensors), state data (e.g., the state data 162), prediction data (e.g., the prediction data 164), a motion plan (e.g., the motion plan 166), and sensor data, map data, etc. associated with the one or more simulated objects.

The machine-learned object detection and prediction model can process the input data to predict an interaction associated with an object (e.g., a sensor-sensor interaction, a sensor-object interaction, and/or an object-object interaction). Moreover, the machine-learned object detection and prediction model can predict one or more interactions for the one or more simulated sensors or the one or more simulated objects including the effect of the simulated sensors on the one or more simulated objects (e.g., the effects of simulated LIDAR on one or more simulated vehicles). Further, the simulation computing system 110 can obtain an output from the machine-learned object detection and prediction model. The output from the machine-learned object detection and prediction model can be indicative of the one or more predicted interactions (e.g., the effect of the one or more simulated sensors on the one or more simulated objects). For example, the output can be indicative of the one or more predicted interactions and/or interaction trajectories of one or more objects within an environment. In some implementations, the simulation computing system 110 can provide input data indicative of the predicted interaction and the machine-learned object detection and prediction model can output the predicted interactions based on such input data. In some implementations, the output can also be indicative of a probability associated with each respective interaction.

In some embodiments, the simulation computing system 110 can compare the one or more classified object labels to one or more machine-learned model classified object labels generated by the machine-learned model. For example, the computing system 810 can compare the one or more classified object labels to the one or more machine-learned model classified object labels. The comparison of the one or more classified object labels to the one or more machine-learned model classified object labels can include a comparison of whether the one or more classified object labels match (e.g., are the same as) the one or more machine-learned model classified object labels.

In some embodiments, satisfying the one or more perception criteria can be based at least in part on an amount of one or more differences (e.g., an extent of the one or more differences and/or a number of the one or more differences) between the one or more classified object labels and the one or more machine-learned model classified object labels. In some embodiments, the one or more classified object labels and the one or more machine-learned model classified object labels can have different labels that can be associated with simulated objects that are determined to have effectively the same effect on the one or more simulated sensors. For example, a simulated reflective sheet of glass and a simulated reflective sheet of aluminum with the same reflectivity can have different labels but result in the same effect on a simulated sensor.

FIG. 7 depicts a flow diagram of an example method of sensor testing and optimization according to example embodiments of the present disclosure. One or more portions of a method 700, illustrated in FIG. 7, can be implemented by one or more devices (e.g., one or more computing devices) or systems including, for example, one or more devices or systems of the computing system 100, shown in FIG. 1. Moreover, one or more portions of the method 700 can be implemented as an algorithm on the hardware components of the devices described herein (e.g., as in FIG. 1) to, for example, generate sensor data based in part on a scene including simulated objects associated with simulated physical properties. FIG. 7 depicts elements performed in a particular order for purposes of illustration and discussion. Those of ordinary skill in the art, using the disclosures provided herein, will understand that the elements of any of the methods discussed herein can be adapted, rearranged, expanded, omitted, combined, and/or modified in various ways without deviating from the scope of the present disclosure.

At 702, the method 700 can include receiving physical sensor data based at least in part on one or more physical sensor interactions including detection, by one or more physical sensors, of one or more physical objects and one or more physical pose properties of the one or more physical objects. For example, the simulation computing system 110 can receive physical sensor data based at least in part on one or more physical sensor interactions including a detection by, one or more physical sensors, of one or more physical objects and one or more physical pose properties of the one or more physical objects. By way of further example, the computing device 210 can receive physical sensor data (e.g., the simulated object data 202) based at least in part on one or more physical sensor interactions including a detection by, one or more physical sensors, of one or more physical objects and one or more physical pose properties of the one or more physical objects.

The one or more physical pose properties can include one or more spatial dimensions of one or more physical objects, one or more locations of one or more physical objects, one or more velocities of one or more physical objects, one or more accelerations of one or more physical objects, one or more masses of one or more physical objects, one or more color characteristics of one or more physical objects, a physical reflectiveness of a physical object, a physical reflectance of a physical object, a brightness of a physical object, and/or one or more physical paths associated with the one or more physical objects.

In some embodiments, the scene can be based at least in part on the physical sensor data. For example, one or more physical pose properties (e.g., one or more physical dimensions) of an actual physical location that includes one or more physical objects can be recorded and the one or more physical pose properties can be used to generate a scene using aspects of the one or more physical pose properties of the actual physical location.

At 704, the method 700 can include determining one or more differences between the one or more simulated sensor interactions and the one or more physical sensor interactions. For example, the simulation computing system 110 can determine one or more differences between the one or more simulated sensor interactions and the one or more physical sensor interactions. By way of further example, the computing device 210 can determine one or more differences between the one or more simulated sensor interactions and the one or more physical sensor interactions. The one or more differences can between the one or more simulated sensor interactions and the one or more physical sensor interactions can be determined based on a comparison of one or more properties of the one or more simulated sensor interactions and one or more properties of the one or more physical sensor interactions including the range, point density, and/or accuracy of detection by the one or more simulated sensors and the one or more physical sensors.

Further, the one or more differences can include an indication of the extent to which the one or more simulated sensor interactions correspond to the one or more physical sensor interactions. For example, a numerical value (e.g., a five percent difference in sensor accuracy) can be associated with the determined one or more differences between the one or more simulated sensor interactions and the one or more physical sensor interactions.

At 706, the method 700 can include adjusting the one or more simulated sensor properties of the one or more simulated sensors based at least in part on the one or more differences between the one or more simulated sensor interactions and the one or more physical sensor interactions. By way of example, the simulation computing system 110 can adjust the one or more simulated sensor properties of the one or more simulated sensors based at least in part on the one or more differences between the one or more simulated sensor interactions and the one or more physical sensor interactions. For example, the one or more simulated sensor interactions can include sensor output that is based at least in part on one or more simulated sensor properties indicating that the accuracy of a simulated sensor decreases by half every twenty meters. The differences between the simulated sensor and a physical sensor upon which the simulated sensor is based can show that the accuracy of a physical sensor corresponding to the simulated sensor decreases by a third under a corresponding set of predetermined environmental conditions in an actual physical environment. As such, the one or more simulated interactions can be adjusted so that the accuracy of the simulated sensor under simulated conditions more closely corresponds to the accuracy of the physical sensor in corresponding physical conditions.

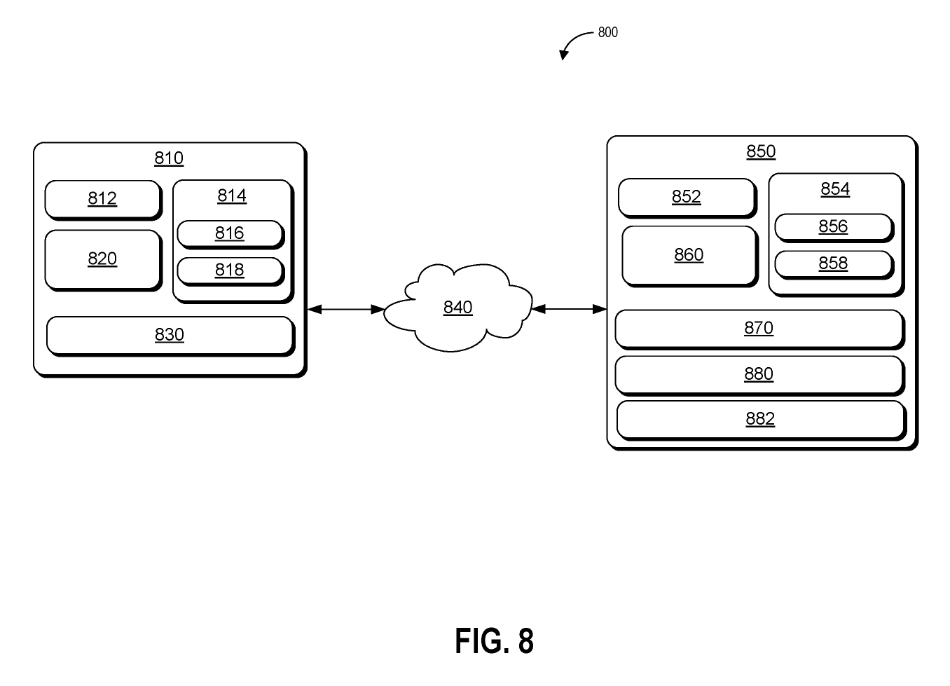

FIG. 8 depicts a block diagram of an example computing system 800 according to example embodiments of the present disclosure. The example system 800 includes a computing system 810 and a machine learning computing system 850 that are communicatively coupled over a network 840.

In some implementations, the computing system 810 can perform various functions and/or operations including obtaining, generating, and/or processing one or more simulated environments which can include one or more simulated objects (e.g., one or more simulated vehicles, simulated buildings, and/or simulated sensors) and simulated sensor interactions. Further, the computing system 810 can include one or more of the features, components, devices, and/or functionality of the simulation computing system 110 and/or the sensor testing system 200. In some implementations, the computing system 810 can be included in an autonomous vehicle. For example, the computing system 810 can be on-board the autonomous vehicle. In other implementations, the computing system 810 is not located on-board the autonomous vehicle. For example, the computing system 810 can operate offline to obtain, generate, and/or process simulations. The computing system 810 can include one or more distinct physical computing devices.

The computing system 810 includes one or more processors 812 and a memory 814. The one or more processors 812 can be any suitable processing device (e.g., a processor core, a microprocessor, an ASIC, a FPGA, a controller, a microcontroller, etc.) and can be one processor or a plurality of processors that are operatively connected. The memory 814 can include one or more non-transitory computer-readable storage media, such as RAM, ROM, EEPROM, EPROM, one or more memory devices, flash memory devices, etc., and combinations thereof.

The memory 814 can store information that can be accessed by the one or more processors 812. For instance, the memory 814 (e.g., one or more non-transitory computer-readable storage mediums, memory devices) can store data 816 that can be obtained, received, accessed, written, manipulated, created, and/or stored. The data 816 can include, for instance, data associated with the generation and/or determination of sensor interactions associated with simulated sensors as described herein. In some implementations, the computing system 810 can obtain data from one or more memory devices that are remote from the system 810.

The memory 814 can also store computer-readable instructions 818 that can be executed by the one or more processors 812. The instructions 818 can be software written in any suitable programming language or can be implemented in hardware. Additionally, or alternatively, the instructions 818 can be executed in logically and/or virtually separate threads on the one or more processors 812.

For example, the memory 814 can store instructions 818 that when executed by the one or more processors 812 cause the one or more processors 812 to perform any of the operations and/or functions described herein, including, for example, obtaining, generating, and/or processing one or more simulated environments which can include one or more simulated objects (e.g., one or more simulated vehicles, simulated buildings, and/or simulated sensors) and simulated sensor interactions.

According to an aspect of the present disclosure, the computing system 810 can store or include one or more machine-learned models 830. As examples, the machine-learned models 830 can be or can otherwise include various machine-learned models such as, for example, neural networks (e.g., deep neural networks), support vector machines, decision trees, ensemble models, k-nearest neighbors models, Bayesian networks, or other types of models including linear models and/or non-linear models. Example neural networks include feed-forward neural networks, recurrent neural networks (e.g., long short-term memory recurrent neural networks), convolutional neural networks, or other forms of neural networks.

In some implementations, the computing system 810 can receive the one or more machine-learned models 830 from the machine learning computing system 850 over network 840 and can store the one or more machine-learned models 830 in the memory 814. The computing system 810 can then use or otherwise implement the one or more machine-learned models 830 (e.g., by the one or more processors 812). In particular, the computing system 810 can implement the one or more machine-learned models 830 to obtain, generate, and/or process one or more simulated environments which can include one or more simulated objects (e.g., one or more simulated vehicles, simulated buildings, and/or simulated sensors) and simulated sensor interactions.

The machine learning computing system 850 includes one or more processors 852 and a memory 854. The one or more processors 852 can be any suitable processing device (e.g., a processor core, a microprocessor, an ASIC, a FPGA, a controller, a microcontroller, etc.) and can be one processor or a plurality of processors that are operatively connected. The memory 854 can include one or more non-transitory computer-readable storage media, such as RAM, ROM, EEPROM, EPROM, one or more memory devices, flash memory devices, etc., and combinations thereof.

The memory 854 can store information that can be accessed by the one or more processors 852. For instance, the memory 854 (e.g., one or more non-transitory computer-readable storage mediums, memory devices) can store data 856 that can be obtained, received, accessed, written, manipulated, created, and/or stored. The data 856 can include, for instance, data associated with one or more simulated environments and/or simulated objects as described herein. In some implementations, the machine learning computing system 850 can obtain data from one or more memory devices that are remote from the system 850.

The memory 854 can also store computer-readable instructions 858 that can be executed by the one or more processors 852. The instructions 858 can be software written in any suitable programming language or can be implemented in hardware. Additionally, or alternatively, the instructions 858 can be executed in logically and/or virtually separate threads on the one or more processors 852.

For example, the memory 854 can store instructions 858 that when executed by the one or more processors 852 cause the one or more processors 852 to perform any of the operations and/or functions described herein, including, for example, obtaining, generating, and/or processing one or more simulated environments which can include one or more simulated objects (e.g., one or more simulated vehicles, simulated buildings, and/or simulated sensors) and simulated sensor interactions.

In some implementations, the machine learning computing system 850 includes one or more server computing devices. If the machine learning computing system 850 includes multiple server computing devices, such server computing devices can operate according to various computing architectures, including, for example, sequential computing architectures, parallel computing architectures, or some combination thereof.

In addition or alternatively to the one or more machine-learned models 830 at the computing system 810, the machine learning computing system 850 can include one or more machine-learned models 870. As examples, the one or more machine-learned models 870 can be or can otherwise include various machine-learned models such as, for example, neural networks (e.g., deep neural networks), support vector machines, decision trees, ensemble models, k-nearest neighbors models, Bayesian networks, or other types of models including linear models and/or non-linear models. Example neural networks include feed-forward neural networks, recurrent neural networks (e.g., long short-term memory recurrent neural networks), convolutional neural networks, or other forms of neural networks.

As an example, the machine learning computing system 850 can communicate with the computing system 810 according to a client-server relationship. For example, the machine learning computing system 850 can implement the one or more machine-learned models 870 to provide a web service to the computing system 810. For example, the web service can provide obtaining, generating, and/or processing one or more simulated environments which can include one or more simulated objects (e.g., one or more simulated vehicles, simulated buildings, and/or simulated sensors) and simulated sensor interactions.

Thus, one or more machine-learned models 830 can located and used at the computing system 810 and/or the one or more machine-learned models 870 can be located and used at the machine learning computing system 850.

In some implementations, the machine learning computing system 850 and/or the computing system 810 can train the one or more machine-learned models 830 and/or the one or more machine-learned models 870 through use of a model trainer 880. The model trainer 880 can train the one or more machine-learned models 830 and/or the one or more machine-learned models 870 using one or more training or learning algorithms. One example training technique is backwards propagation of errors. In some implementations, the model trainer 880 can perform supervised training techniques using a set of labeled training data. In other implementations, the model trainer 880 can perform unsupervised training techniques using a set of unlabeled training data. The model trainer 880 can perform a number of generalization techniques to improve the generalization capability of the models being trained. Generalization techniques include weight decays, dropouts, or other techniques.

In particular, the model trainer 880 can train the one or more machine-learned models 830 and/or the one or more machine-learned models 870 based on a set of training data 882. The training data 882 can include, for example, a plurality of objects including vehicle objects, pedestrian objects, cyclist objects, building objects, and/or road objects, which can be associated with various characteristics and/or properties (e.g., physical dimensions, velocity, and/or travel path). The model trainer 880 can be implemented in hardware, firmware, and/or software controlling one or more processors.

The computing system 810 can also include a network interface 820 used to communicate with one or more systems or devices, including systems or devices that are remotely located from the computing system 810. The network interface 820 can include any circuits, components, software, etc. for communicating with one or more networks (e.g., the network 840). In some implementations, the network interface 820 can include, for example, one or more of a communications controller, receiver, transceiver, transmitter, port, conductors, software and/or hardware for communicating data. Similarly, the machine learning computing system 850 can include a network interface 860.

The network 840 can be any type of network or combination of one or more networks that allows for communication between devices. In some embodiments, the one or more networks can include one or more of a local area network, wide area network, the Internet, secure network, cellular network, mesh network, peer-to-peer communication link and/or some combination thereof and can include any number of wired or wireless links. Communication over the networks 840 can be accomplished, for instance, via a network interface using any type of protocol, protection scheme, encoding, format, packaging, etc.

FIG. 8 illustrates one example computing system 800 that can be used to implement the present disclosure. Other computing systems can be used as well. For example, in some implementations, the computing system 810 can include the model trainer 880 and the training dataset 882. In such implementations, the one or more machine-learned models 830 can be both trained and used locally at the computing system 810. As another example, in some implementations, the computing system 810 is not connected to other computing systems.

In addition, components illustrated and/or discussed as being included in one of the computing systems 810 or 850 can instead be included in another of the computing systems 810 or 850. Such configurations can be implemented without deviating from the scope of the present disclosure. The use of computer-based systems allows for a great variety of possible configurations, combinations, and divisions of tasks and functionality between and among components. Computer-implemented operations can be performed on a single component or across multiple components. Computer-implemented tasks and/or operations can be performed sequentially or in parallel. Data and instructions can be stored in a single memory device or across multiple memory devices.

While the present subject matter has been described in detail with respect to specific example embodiments and methods thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A computer-implemented method of sensor optimization for an autonomous vehicle, the computer-implemented method comprising:
obtaining, by a computing system comprising one or more computing devices, a scene comprising one or more simulated objects associated with one or more simulated physical properties;
generating, by the computing system, sensor data comprising one or more simulated sensor interactions for the scene, the one or more simulated sensor interactions comprising one or more simulated sensors detecting the one or more simulated objects, wherein the one or more simulated sensors comprise one or more simulated sensor properties;
determining, by the computing system and based in part on the sensor data, that the one or more simulated sensor interactions satisfy one or more perception criteria of an autonomous vehicle perception system; and
in response to determining that the one or more simulated sensor interactions satisfy the one or more perception criteria, generating, by the computing system, one or more changes for the autonomous vehicle perception system.

2. The computer-implemented method of claim 1,
wherein the one or more simulated sensor interactions comprise one or more obfuscating interactions that reduce detection capabilities of the one or more simulated sensors, and
wherein the method further comprises adjusting, by the computing system, the one or more simulated sensor properties of the one or more simulated sensors based at least in part on the one or more obfuscating interactions that reduce the detection capabilities of the one or more simulated sensors.

3. The computer-implemented method of claim 2, wherein the one or more obfuscating interactions comprise at least one of sensor cross-talk, sensor noise, sensor blooming, relative velocity distortion, sensor lens distortion, sensor tangential distortion, sensor banding, range related sensor signal loss, or sensor color imbalance.

4. The computer-implemented method of claim 1, wherein the one or more simulated sensors comprise a spinning sensor having a detection capability that is based in part on a simulated relative velocity distortion associated with a spin rate of the spinning sensor and a velocity of the one or more objects relative to the spinning sensor.

5. The computer-implemented method of claim 1,
wherein generating the sensor data further comprises generating, by the computing system, the sensor data based at least in part on a detection, by the one or more simulated sensors, of the one or more simulated objects from a plurality of simulated sensor positions within the scene,
wherein each of the plurality of simulated sensor positions comprises an x-coordinate location, a y-coordinate location, and a z-coordinate location of the one or more simulated sensors with respect to a ground plane of the scene, or an angle of the one or more simulated sensors with respect to a ground plane of the scene, and
wherein the one or more simulated sensor interactions are based at least in part on the detection of the one or more simulated objects from the plurality of simulated sensor positions within the scene.

6. The computer-implemented method of claim 1,
wherein generating the sensor data further comprises generating, by the computing system, the sensor data based at least in part on a detection, by the one or more simulated sensors, of the one or more simulated objects using a plurality of simulated sensor types,
wherein for each of the plurality of simulated sensor types, the one or more simulated sensor properties, or values associated with the one or more simulated sensor properties are different, and
wherein the one or more simulated sensor interactions are based at least in part on the detection of the one or more simulated objects using the plurality of simulated sensor types.

7. The computer-implemented method of claim 1,
wherein generating the sensor data further comprises generating, by the computing system, the sensor data based at least in part on a detection, by one or more simulated sensors, of the one or more simulated objects using a plurality of activation sequences, the plurality of activation sequences comprising an order and a timing of activating the one or more simulated sensors, and
wherein the one or more simulated sensor interactions are based at least in part on the detection of the one or more simulated objects in the plurality of activation sequences.

8. The computer-implemented method of claim 1,
wherein generating the sensor data further comprises generating, by the computing system, the sensor data based at least in part on a detection, by the one or more simulated sensors, of the one or more simulated objects based in part on a plurality of utilization levels associated with a number of the one or more simulated sensors that are activated at a time, and
wherein the one or more simulated sensor interactions are based at least in part on the detection of the one or more simulated objects based in part on the plurality of utilization levels.

9. The computer-implemented method of claim 1,
wherein generating the sensor data further comprises generating, by the computing system, the sensor data based at least in part on a detection, by the one or more simulated sensors, of the one or more simulated objects using a plurality of sample rates associated with a frequency with which the one or more simulated sensors detect the one or more simulated objects, and
wherein the one or more simulated sensor interactions are based in part on the detection of the one or more simulated objects using the plurality of sample rates.

10. The computer-implemented method of claim 1, further comprising:
associating, by the computing system, the one or more simulated objects of the sensor data with one or more classified object labels; and
sending, by the computing system, the sensor data comprising the one or more simulated objects associated with the one or more classified object labels to a machine-learned model associated with the autonomous vehicle perception system, wherein the sensor data is used to train the machine-learned model.

11. The computer-implemented method of claim 1, wherein the one or more simulated sensor properties are based at least in part on one or more sensor properties of one or more physical sensors comprising one or more light detection and ranging devices (LIDAR), one or more radar devices, one or more sonar devices, or one or more cameras.

12. The computer-implemented method of claim 11, further comprising:
receiving, by the computing system, physical sensor data based at least in part on one or more physical sensor interactions comprising a detection by, one or more physical sensors, of one or more physical objects and one or more physical pose properties of the one or more physical objects, the one or more physical pose properties comprising one or more physical spatial dimensions, one or more physical locations, one or more physical velocities, or one or more physical paths associated with the one or more physical objects, wherein the scene is based at least in part on the physical sensor data.

13. The computer-implemented method of claim 12, further comprising:
determining, by the computing system, one or more differences between the one or more simulated sensor interactions and the one or more physical sensor interactions; and
adjusting, by the computing system, the one or more simulated sensor properties of the one or more simulated sensors based at least in part on the one or more differences between the one or more simulated sensor interactions and the one or more physical sensor interactions.

14. The computer-implemented method of claim 1, wherein the one or more simulated sensor properties of the one or more simulated sensors comprise a spin rate, a point density, a field of view, a height, a frequency, an amplitude, a focal length, a range, a sensitivity, a latency, a linearity, or a resolution.

15. The computer-implemented method of claim 1, wherein the one or more simulated physical properties of the one or more simulated objects comprise one or more spatial dimensions, one or more locations, one or more velocities, or one or more paths.

16. One or more tangible, non-transitory computer-readable media storing computer-readable instructions that when executed by one or more processors cause the one or more processors to perform operations, the operations comprising:
obtaining a scene comprising one or more simulated objects associated with one or more simulated physical properties;
generating sensor data comprising one or more simulated sensor interactions for the scene, the one or more simulated sensor interactions comprising one or more simulated sensors detecting the one or more simulated objects, wherein the one or more simulated sensors comprise one or more simulated sensor properties;
determining, based at least in part on the sensor data, that the one or more simulated sensor interactions satisfy one or more perception criteria of an autonomous vehicle perception system; and
in response to determining that the one or more simulated sensor interactions satisfy the one or more perception criteria, generating, one or more changes for the autonomous vehicle perception system.

17. The one or more tangible, non-transitory computer-readable media of claim 16, further comprising:
associating the one or more simulated objects of the sensor data with one or more classified object labels; and
sending the sensor data comprising the one or more simulated objects associated with the one or more classified object labels to a machine-learned model associated with the autonomous vehicle perception system, wherein the sensor data is used to train the machine-learned model.

18. A computing system comprising:
one or more processors;
a memory comprising one or more computer-readable media, the memory storing computer-readable instructions that when executed by the one or more processors cause the one or more processors to perform operations comprising:
obtaining a scene comprising one or more simulated objects associated with one or more simulated physical properties;
generating sensor data comprising one or more simulated sensor interactions for the scene, the one or more simulated sensor interactions comprising one or more simulated sensors detecting the one or more simulated objects, wherein the one or more simulated sensors comprise one or more simulated sensor properties;
determining, based at least in part on the sensor data, the one or more simulated sensor interactions that satisfy one or more perception criteria of an autonomous vehicle perception system; and
in response to determining that the one or more simulated sensor interactions satisfy the one or more perception criteria, generating one or more changes for the autonomous vehicle perception system.

19. The computing system of claim 18, wherein the one or more simulated sensor interactions comprise one or more sensor miscalibration interactions associated with inaccurate placement of the one or more simulated sensors that reduces detection accuracy of the one or more simulated sensors, and
wherein the operations further comprise adjusting the one or more simulated sensor properties of the one or more simulated sensors based at least in part on the one or more sensor miscalibration interactions that reduce the accuracy of the one or more simulated sensors.

20. The computing system of claim 18, further comprising:
associating the one or more simulated objects of the sensor data with one or more classified object labels; and
sending the sensor data comprising the one or more simulated objects associated with the one or more classified object labels to a machine-learned model associated with the autonomous vehicle perception system, wherein the sensor data is used to train the machine-learned model.
